(19) United States
(12) Patent Application Publication
(10) Pub. No.: US 2025/0314716 A1
(43) Pub. Date: Oct. 9, 2025

(54) SEMICONDUCTOR DEVICE

(71) Applicant: ROHM CO., LTD., Kyoto-shi (JP)

(72) Inventor: Tatsuya NINOMIYA, Kyoto-shi (JP)

(21) Appl. No.: 19/095,197

(22) Filed: Mar. 31, 2025

(30) Foreign Application Priority Data
Apr. 3, 2024 (JP) 2024-060275

(51) Int. Cl. G01R 33/00; G01R 15/20; G01R 19/00

(52) U.S. Cl. CPC G01R 33/0047; G01R 15/202; G01R 15/207; G01R 19/0092; G01R 33/007

(57) ABSTRACT

A semiconductor device includes a substrate including a first substrate surface and a second substrate surface opposite to the first substrate surface, a first wiring pattern provided on the first substrate surface, and a sensor chip used to detect a current flowing through the first wiring pattern. The first wiring pattern includes a detection pattern having a predetermined width. The sensor chip is mounted on the first substrate surface in a state of being disposed to cross the detection pattern. The sensor chip includes a first detection element and a second detection element as detection elements that detect a magnetic field generated by a current flowing through the detection pattern.

### CROSS REFERENCE TO RELATED APPLICATIONS

The present invention claims priority under 35 U.S.C. § 119 to Japanese Application No. 2024-060275, filed on Apr. 3, 2024, the entire contents of which being incorporated herein by reference.

### TECHNICAL FIELD

The present disclosure relates to a semiconductor device.

### BACKGROUND

Patent Document 1 discloses a magnetic field sensor that includes a first magnetic field detection part and a second magnetic field detection part and detects a magnetic field generated by a current flowing through a wiring of a printed circuit board. The wiring includes a forward path part, a return path part where a current flows in an opposite direction to the forward path part, and a connecting part that connects the forward path part and the return path part. In addition, the magnetic field sensor is disposed such that the first magnetic field detection part detects a magnetic field of the forward path part, and the second magnetic field detection part detects a magnetic field of the return path part.

### PRIOR ART DOCUMENT

### Patent Publication

[Patent document 1] Japan Patent Publication No. 2021-85711.

### BRIEF DESCRIPTION OF THE DRAWINGS

FIG. 1 is a schematic perspective view of an exemplary semiconductor device according to a first embodiment.

FIG. 2 is a schematic side view of a substrate of the semiconductor device of FIG. 1.

FIG. 3 is a schematic side view of the substrate of the semiconductor device of FIG. 1 when viewed from a different direction than that of FIG. 2.

FIG. 4 is a schematic plan view of a wiring pattern provided on the substrate of FIG. 1.

FIG. 5 is an enlarged schematic plan view of a sensor chip and its periphery in the semiconductor device of FIG. 1.

FIG. 6 is a schematic cross-sectional view of the semiconductor device cut along a line F6-F6 of FIG. 5.

FIG. 7 is an enlarged schematic cross-sectional view of the sensor chip of FIG. 6.

FIG. 8 is a schematic circuit diagram showing a circuit configuration of the sensor chip of FIG. 6.

FIG. 9 is a schematic circuit diagram showing the circuit configuration of an inverter device to which the semiconductor device of the first embodiment is applied.

FIG. 10 is an enlarged schematic plan view of the semiconductor device and its periphery in the inverter device of FIG. 9.

FIG. 11 is an enlarged schematic plan view of a sensor chip and its periphery in an exemplary semiconductor device according to a second embodiment.

FIG. 12 is an enlarged schematic plan view of a sensor chip and its periphery in an exemplary semiconductor device according to a third embodiment.

FIG. 13 is a schematic cross-sectional view of the sensor chip cut along a line F13-F13 of FIG. 12.

FIG. 14 is a schematic perspective view of a semiconductor device in a modified example.

FIG. 15 is a schematic side view of a substrate of the semiconductor device of FIG. 14.

FIG. 16 is a schematic side view of the substrate of the semiconductor device of FIG. 14 when viewed from a different direction than that of FIG. 15.

FIG. 17 is a schematic plan view of a wiring pattern in a semiconductor device of a modified example.

FIG. 18 is a schematic plan view of a wiring pattern in a semiconductor device of a modified example.

FIG. 19 is an enlarged schematic cross-sectional view of a sensor chip and its periphery in the semiconductor device of a modified example.

FIG. 20 is an enlarged schematic plan view of the sensor chip and its periphery in a semiconductor device of a modified example.

FIG. 21 is a schematic plan view of a semiconductor device of a modified example.

FIG. 22 is a schematic plan view of a semiconductor device of a modified example.

FIG. 23 is a schematic plan view of the sensor chip in the semiconductor device of a modified example.

FIG. 24 is a schematic cross-sectional view of the sensor chip cut along a line F24-F24 of FIG. 23.

### DETAILED DESCRIPTION OF THE EMBODIMENTS

Hereinafter, several embodiments of a semiconductor device in the present disclosure are described with reference to accompanying figures. Furthermore, for simplicity and clarity of description, components shown in the figures are not necessarily drawn to a specific scale. Additionally, to facilitate understanding, hatching lines may be omitted in cross-sectional views. The accompanying figures are merely illustrative of the embodiments of the present disclosure and should not be considered as limiting the present disclosure.

The following detailed description includes devices, systems, and methods embodying exemplary embodiments of the present disclosure. This detailed description is merely illustrative and is not intended to limit embodiments of the present disclosure or the application and use of such embodiments.

The phrase “at least one” as used in the present disclosure means “one or more” of a desired option. As an example, the phrase “at least one” as used in the present disclosure means “only one option” or “both of two options” if the number of options is two. As another example, the phrase “at least one” as used in the present disclosure means “only one option” or “any combination of two or more options” if the number of options is three or more.

As used in the present disclosure, “a dimension (width, length) of A is equal to a dimension (width, length) of B” or “a dimension (width, length) of A and a dimension (width, length) of B are equal to each other” also includes a relationship in which a difference between the dimension (width, length) of A and the dimension (width, length) of B is, for example, within 10% of the dimension (width, length) of A.

### First Embodiment

### [Overall Configuration of Semiconductor Device]

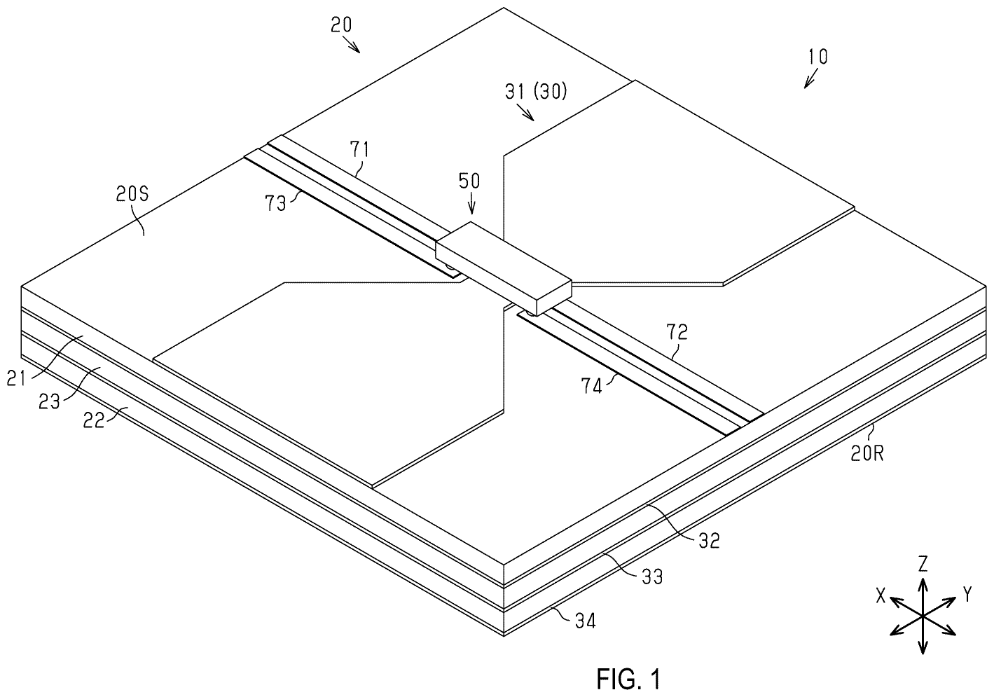

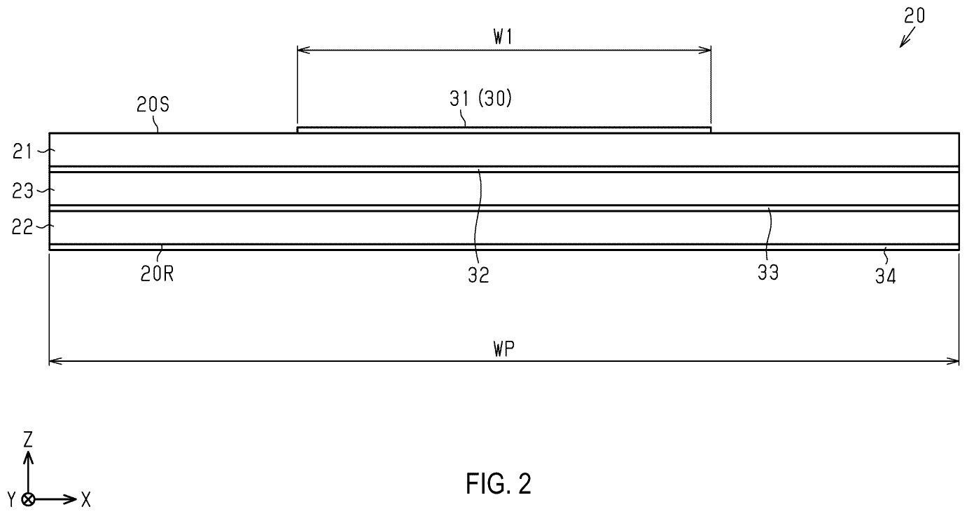

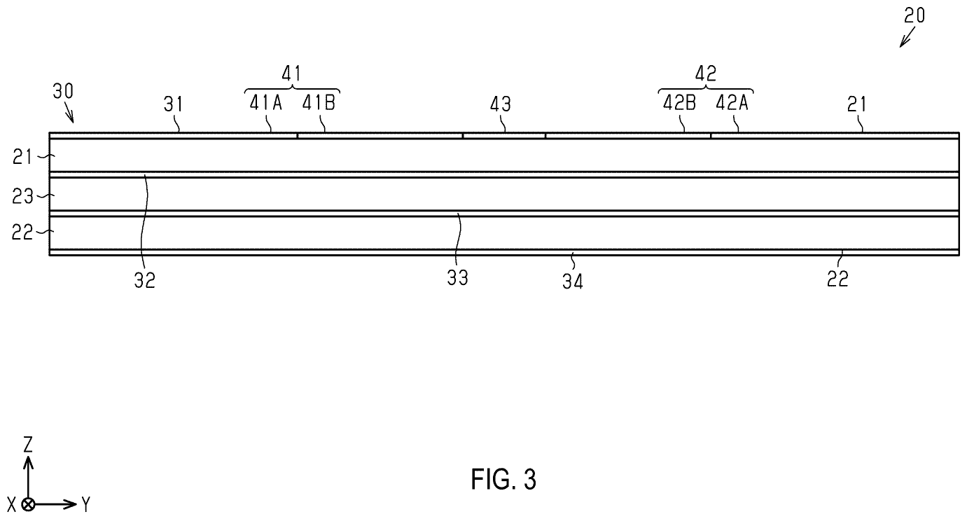

Referring to FIGS. 1 to FIG. 3, a configuration of a semiconductor device 10 in a first embodiment is described. FIG. 1 schematically shows a perspective structure of the semiconductor device 10 in the first embodiment. FIG. 2 schematically shows a side structure of a substrate 20 of the semiconductor device 10 in FIG. 1, which is described later. FIG. 3 schematically shows a structure of the substrate 20 when viewed from a different direction than that of FIG. 2.

As shown in FIG. 1, the semiconductor device 10 includes the substrate 20, a wiring pattern 30 provided on the substrate 20, and a sensor chip 50 mounted on the substrate 20.

The substrate 20 is formed of an insulating material such as glass epoxy resin. The substrate 20 is in a form of a flat plate with its thickness direction in the Z direction. The substrate 20 includes a first substrate surface 20S and a second substrate surface 20R opposite to the first substrate surface 20S. Furthermore, in the following description, a “plan view” refers to viewing the semiconductor device 10 from the Z direction. Therefore, a plan view means the same as “when viewed from a thickness direction of the substrate 20.”

As shown in FIG. 2 and FIG. 3, the substrate 20 is formed of a multilayer substrate. In the example shown in FIG. 2 and FIG. 3, the substrate 20 is a four-layer substrate. More specifically, the substrate 20 includes a first base material 21, a second base material 22, and a third base material 23. The first base material 21 includes the first substrate surface 20S. The second base material 22 includes the second substrate surface 20R. The third base material 23 is provided between the first base material 21 and the second base material 22 in the Z direction.

The wiring pattern 30 forms part of a conductive layer of the multilayer substrate. More specifically, the wiring pattern 30 includes a first wiring pattern 31 provided on the first substrate surface 20S. In the first embodiment, the semiconductor device 10 further includes a first heat dissipation pattern 32 provided between the first base material 21 and the third base material 23, a second heat dissipation pattern 33 provided between the third base material 23 and the second base material 22, and a third heat dissipation pattern 34 provided on the second base material 22. It can also be said that the first wiring pattern 31 is provided on the first substrate surface 20S. It can also be said that the third heat dissipation pattern 34 is provided on the second substrate surface 20R. Herein, each of the first to third heat dissipation patterns 32 to 34 is an example of a “heat dissipation pattern.” Furthermore, the detailed structure of each of the first wiring pattern 31 and the first to third heat dissipation patterns 32 to 34 is described later.

The first wiring pattern 31, the first heat dissipation pattern 32, the second heat dissipation pattern 33, and the third heat dissipation pattern 34 are formed of conductive materials such as copper (Cu), aluminum (Al), titanium (Ti), titanium nitride (TiN), etc. In one example, each of the first wiring pattern 31, the first heat dissipation pattern 32, the second heat dissipation pattern 33, and the third heat dissipation pattern 34 is formed of the same material as each other. In the first embodiment, each of the first wiring pattern 31, the first heat dissipation pattern 32, the second heat dissipation pattern 33, and the third heat dissipation pattern 34 is formed of a material including Cu. Furthermore, the first wiring pattern 31 and the first to third heat dissipation patterns 32 to 34 may be formed of different materials from each other.

As shown in FIG. 1, the sensor chip 50 is used to detect a current flowing through the wiring pattern 30 (in the first embodiment, the first wiring pattern 31). The sensor chip 50 is mounted on the first substrate surface 20S of the substrate 20. More specifically, the sensor chip 50 is mounted on first to fourth sensor patterns 71 to 74 provided on the first substrate surface 20S. Furthermore, detailed configurations of the sensor chip 50 and the first to fourth sensor patterns 71 to 74 are described later.

### [Configuration of Wiring Pattern]

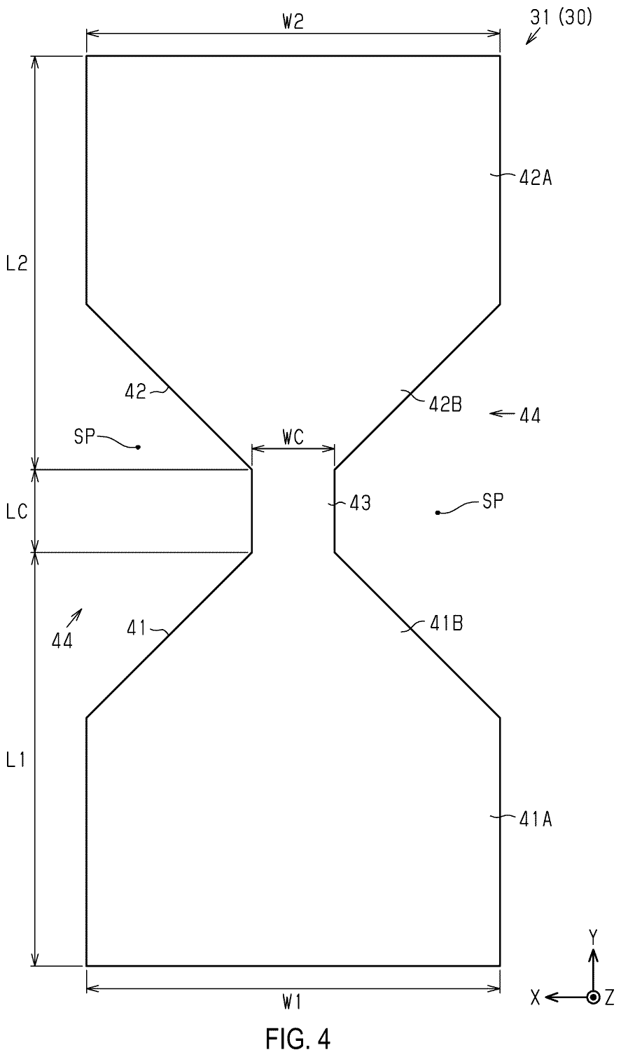

Referring to FIGS. 2 to FIG. 4, the detailed configuration of the wiring pattern 30 is described. FIG. 4 schematically shows a planar structure of the first wiring pattern 31.

As shown in FIG. 4, the first wiring pattern 31 includes a first pattern 41, a second pattern 42, and a detection pattern 43. The first pattern 41, the second pattern 42, and the detection pattern 43 are disposed side by side in the Y direction. The detection pattern 43 is disposed between the first pattern 41 and the second pattern 42 in the Y direction.

The first pattern 41 extends in the Y direction. The first pattern 41 has a first width W1, which is a length in the X direction. The first pattern 41 includes a first portion 41A and a second portion 41B. The first portion 41A and the second portion 41B are disposed side by side in the Y direction. Herein, the Y direction is an example of the “first direction.”

The first portion 41A is a portion of the first pattern 41 that has the first width W1. In one example, the first portion 41A extends in the Y direction with a constant width of the first width W1. The first portion 41A is disposed on a side of the second portion 41B that is opposite to the detection pattern 43 in the Y direction. Furthermore, the shape of the first portion 41A in the plan view can be changed arbitrarily. In one example, the first width W1 of the first portion 41A may be varied in the Y direction.

The second portion 41B is a portion that connects the first portion 41A and the detection pattern 43. The second portion 41B is provided so as to narrow from the first portion 41A toward the detection pattern 43 in the plan view. In the example shown in FIG. 4, the second portion 41B has a tapered shape that gradually narrows from the first portion 41A toward the detection pattern 43 in the plan view.

The second pattern 42 is disposed spaced apart from the first pattern 41 in the Y direction. The second pattern 42 extends in the Y direction. The second pattern 42 has a second width W2, which is a length in the X direction. The second pattern 42 includes a first portion 42A and a second portion 42B. The first portion 42A and the second portion 42B are disposed side by side in the Y direction.

The first portion 42A is a portion of the second pattern 42 that has the second width W2. In one example, the first portion 42A extends in the Y direction with a constant width of the second width W2. The first portion 42A is disposed on a side of the second portion 42B that is opposite to the detection pattern 43 in the Y direction. Furthermore, the shape of the first portion 42A in the plan view can be changed arbitrarily. In one example, the second width W2 of the first portion 42A may be varied in the Y direction.

The second portion 42B is a portion that connects the first portion 42A and the detection pattern 43. The second portion 42B is provided so as to narrow from the first portion 42A toward the detection pattern 43 in the plan view. In the example shown in FIG. 4, the second portion 42B has a tapered shape that gradually narrows from the first portion 42A toward the detection pattern 43 in the plan view.

In the example shown in FIG. 4, the second width W2 of the first portion 42A of the second pattern 42 is equal to the first width W1 of the first portion 41A of the first pattern 41. Additionally, a taper angle of the second portion 42B of the second pattern 42 is equal to a taper angle of the second portion 41B of the first pattern 41. A length of the second portion 42B of the second pattern 42 in the Y direction is equal to a length of the second portion 41B of the first pattern 41 in the Y direction.

The detection pattern 43 connects the first pattern 41 and the second pattern 42. The detection pattern 43 has a predetermined width. Herein, a width of the detection pattern 43 is defined by a length of the detection pattern 43 in the X direction. It can be said that the X direction is an example of the “second direction.” Additionally, it can be said that the X direction is an example of the “width direction of the detection pattern.” The detection pattern 43 extends in the Y direction in the plan view. Therefore, it can be said that the Y direction is the “direction in which the detection pattern extends.” The detection pattern 43 has a constant width throughout the Y direction. Hereinafter, the width of the detection pattern 43 may be referred to as a “connection width WC.”

In one example, the connection width WC of the detection pattern 43 is narrower than the first width W1 of the first pattern 41 and the second width W2 of the second pattern 42. In one example, the connection width WC of the detection pattern 43 is 1 mm. A length LC of the detection pattern 43 in the Y direction is shorter than a length L1 of the first pattern 41 in the Y direction and a length L2 of the second pattern 42 in the Y direction. In one example, the length LC of the detection pattern 43 in the Y direction is shorter than a length of the second portion 41B of the first pattern 41 in the Y direction and a length of the second portion 42B of the second pattern 42 in the Y direction. In the example shown in FIG. 4, the length LC of the detection pattern 43 in the Y direction is 1 mm.

The first to third heat dissipation patterns 32 to 34 extend in the Y direction. In one example, the first to third heat dissipation patterns 32 to 34 have the same size and shape as each other. As shown in FIG. 2, each of the first to third heat dissipation patterns 32 to 34 has a heat dissipation width WP larger than the first width W1 of the first pattern 41. Herein, as described above, since the first width W1 of the first pattern 41 is equal to the second width W2 of the second pattern 42, the heat dissipation width WP of the first to third heat dissipation patterns 32 to 34 is larger than the second width W2 of the second pattern 42.

### [Configuration of Sensor Chip]

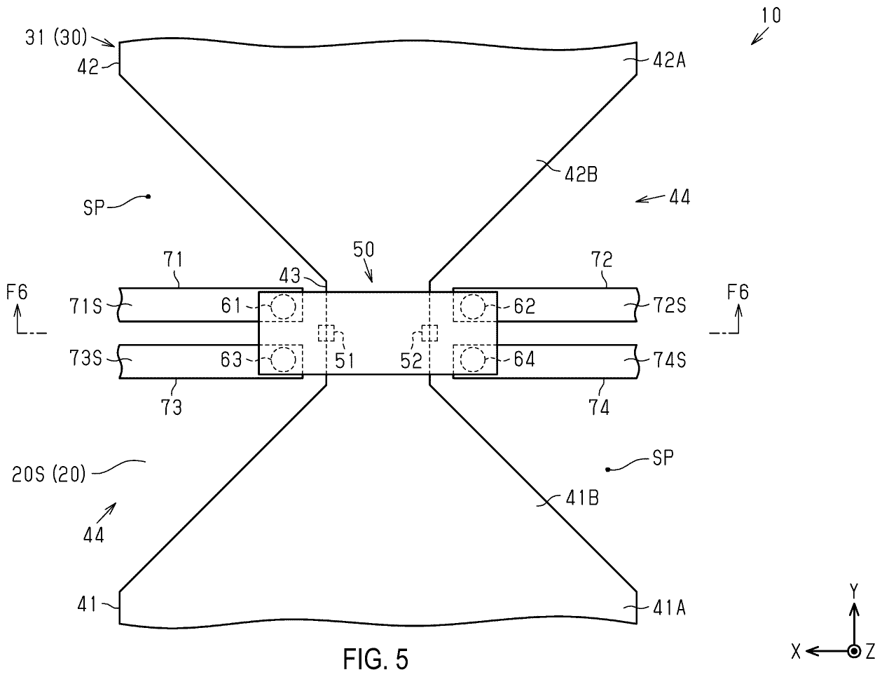

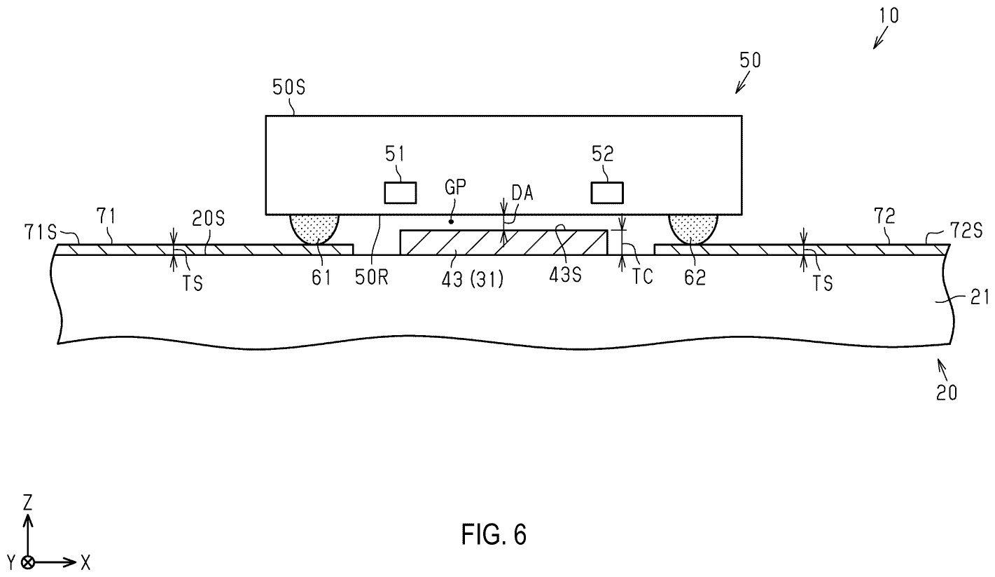

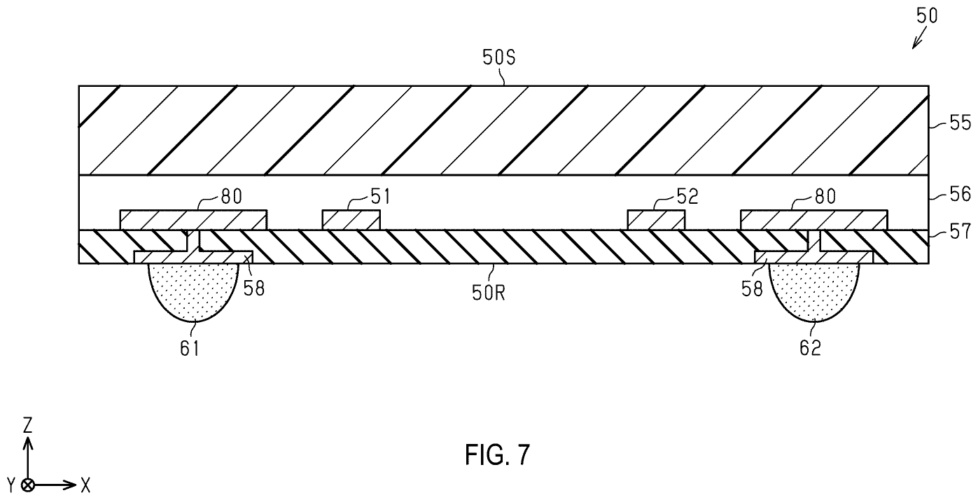

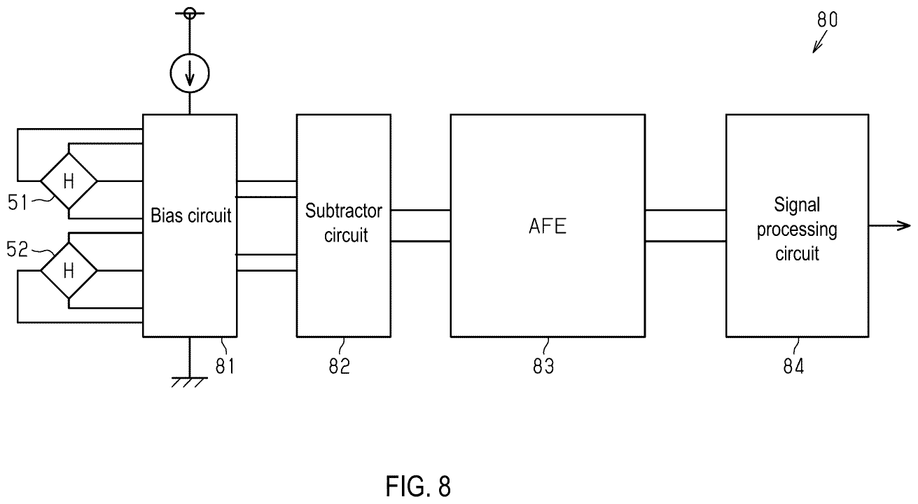

Referring to FIGS. 5 to FIG. 8, a detailed configuration of the sensor chip 50 is described. FIG. 5 schematically shows part of a planar structure of the semiconductor device 10 in a state in which the sensor chip 50 is mounted on the substrate 20. FIG. 6 schematically shows a cross-sectional structure of the semiconductor device 10 cut along a line F6-F6 in FIG. 5. FIG. 7 shows a detailed cross-sectional structure of the sensor chip 50 in FIG. 6. FIG. 8 schematically shows an example of a circuit configuration of the sensor chip 50.

As shown in FIG. 5, the sensor chip 50 is mounted on the first substrate surface 20S of the substrate 20 in a state of being disposed to cross the detection pattern 43 of the wiring pattern 30. The sensor chip 50 has a rectangular shape having a long side and a short side in the plan view. The sensor chip 50 is disposed such that the long side is along the X direction and the short side is along the Y direction.

As shown in FIG. 5 and FIG. 6, a package structure of the sensor chip 50 is a WLCSP (Wafer Level Chip Size Package). The sensor chip 50 includes a first chip surface 50S and a second chip surface 50R opposite to the first chip surface 50S. The second chip surface 50R faces the detection pattern 43. The second chip surface 50R is provided with a plurality of (four in the first embodiment) terminals 61 to 64. The terminals 61 to 64 are formed of, for example, solder bumps.

The terminals 61 to 64 are disposed dispersedly at both ends of the sensor chip 50 in the X direction. The terminals 61, 63 are disposed at one end of the sensor chip 50. The terminals 62, 64 are disposed at the other end of the sensor chip 50. The terminal 61 is formed as, for example, a ground terminal. The terminal 62 is, for example, a REFOUT terminal used to set an output current of the sensor chip 50. The terminal 63 is formed as, for example, a power supply terminal. The terminal 64 is formed as, for example, a signal output terminal.

The terminals 61, 63 and the terminals 62, 64 are disposed dispersedly on both sides of the detection pattern 43 in the X direction in the plan view. Meanwhile, the terminals 61 to 64 are disposed in a recess 44 formed by the second portion 41B of the first pattern 41, the detection pattern 43, and the second portion 42B of the second pattern 42 in the plan view. In other words, the terminals 61 to 64 are between the first portion 41A of the first pattern 41 and the first portion 42A of the second pattern 42 in the Y direction, and are disposed in a space SP formed by the first portions 41A, 42A to the second portions 41B, 42B and the detection pattern 43. In the first embodiment, the space SP is trapezoidal with the detection pattern 43 as an upper base. As such, the plurality of terminals 61 to 64 are disposed inside outer edges of the first pattern 41 and the second pattern 42. Herein, the outer edges of the first pattern 41 are both end edges of the first portion 41A of the first pattern 41 in the X direction. The outer edges of the second pattern 42 are both end edges of the first portion 42A of the second pattern 42 in the X direction.

The terminals 61 to 64 are individually connected to first to fourth sensor patterns 71 to 74 provided on the first substrate surface 20S. As shown in FIG. 6, both an upper surface 71S of the first sensor pattern 71 and an upper surface 72S of the second sensor pattern 72 are disposed closer to the first substrate surface 20S than an upper surface 43S of the detection pattern 43. That is, it can be said that a thickness TS of each of the first sensor pattern 71 and the second sensor pattern 72 is thinner than a thickness TC of the detection pattern 43. Furthermore, although not shown, both an upper surface 73S of the third sensor pattern 73 and an upper surface 74S of the fourth sensor pattern 74 are also disposed closer to the first substrate surface 20S than the upper surface 43S of the detection pattern 43. That is, a thickness of each of the third sensor pattern 73 and the fourth sensor pattern 74 is thinner than the thickness TC of the detection pattern 43. Furthermore, the thicknesses of the first to fourth sensor patterns 71 to 74 may be equal to each other.

In a state where the sensor chip 50 is mounted on the first to fourth sensor patterns 71 to 74, a gap GP is provided between the sensor chip 50 and the detection pattern 43 in the Z direction. That is, the sensor chip 50 is in a non-contact state with the wiring pattern 30. Herein, due to the relationship between the detection pattern 43 and the first to fourth sensor patterns 71 to 74 as described above, the second chip surface 50R of the sensor chip 50 is proximate to the detection pattern 43 in the Z direction. In one example, a distance DA between the second chip surface 50R of the sensor chip 50 and the upper surface 43S of the detection pattern 43 in the Z direction is smaller than the thickness TC of the detection pattern 43. Furthermore, the distance DA can be changed arbitrarily. In one example, the distance DA may be equal to or greater than the thickness TC of the detection pattern 43. Additionally, the sensor chip 50 may be in contact with the upper surface 43S of the detection pattern 43. That is, the distance DA may be zero.

As shown in FIGS. 5 to FIG. 7, the sensor chip 50 includes a first detection element 51 and a second detection element 52 that detect a magnetic field generated by a current flowing through the detection pattern 43. Herein, both the first detection element 51 and the second detection element 52 are examples of “detection elements.” The first detection element 51 and the second detection element 52 are, for example, Hall elements. Furthermore, the first detection element 51 and the second detection element 52 are not limited to Hall elements, and magnetic impedance elements (MI elements) or magnetoresistive effect elements (MR elements) may also be used.

In the plan view, the first detection element 51 and the second detection element 52 are disposed at the same position as each other in the Y direction and are spaced apart from each other in the X direction. Therefore, it can be said that the first detection element 51 and the second detection element 52 are disposed opposite to each other in the X direction. In one example, the first detection element 51 and the second detection element 52 are disposed on both sides of the detection pattern 43 in the X direction in the plan view. That is, the first detection element 51 is disposed closer to one side in the X direction than a center of the detection pattern 43 in the X direction in the plan view. The second detection element 52 is disposed closer to the other side than the center of the detection pattern 43 in the X direction in the plan view. In one example, the first detection element 51 and the second detection element 52 are disposed at positions opposite to both end edges of the detection pattern 43 in the X direction in the Z direction. In the first embodiment, the first detection element 51 is disposed to cross one end edge of the detection pattern 43 in the X direction in the plan view. The second detection element 52 is disposed to cross the other end edge of the detection pattern 43 in the X direction in the plan view.

As shown in FIG. 7, the sensor chip 50 includes a semiconductor substrate 55 and a semiconductor layer 56 provided on the semiconductor substrate 55.

The semiconductor substrate 55 has a rectangular flat plate shape with the thickness direction in the Z direction. The semiconductor substrate 55 includes, for example, a first chip surface 50S. The semiconductor substrate 55 is formed of a material including one of indium antimonide (InSb), indium arsenide (InAs), gallium arsenide (GaAs), and silicon (Si).

The semiconductor layer 56 is a layer in which, for example, the first detection element 51 and the second detection element 52 as Hall elements are provided. The semiconductor layer 56 is formed, for example, by epitaxial growth from the semiconductor substrate 55. An arithmetic circuit 80 is provided in the semiconductor layer 56. The arithmetic circuit 80 is electrically connected to both the first detection element 51 and the second detection element 52. In one example, the arithmetic circuit 80 is provided outward in the X direction from both the first detection element 51 and the second detection element 52. Furthermore, the position where the arithmetic circuit 80 is provided can be changed arbitrarily. Additionally, a configuration of the arithmetic circuit 80 is described later.

A side of the semiconductor layer 56 opposite to the semiconductor substrate 55 in the Z direction is covered by an insulating layer 57. The insulating layer 57 is formed of at least one of silicon oxide (SiO₂), silicon nitride (SiN), and photosensitive resin material. It can also be said that the insulating layer 57 is a protective layer of the sensor chip 50.

The sensor chip 50 is provided with a wiring 58 that electrically connects the arithmetic circuit 80 and the terminals 61 to 64. The wiring 58 is provided in the insulating layer 57. The wiring 58 is formed of conductive materials such as Al, Cu, Ti, TiN, W, etc. Furthermore, the wiring 58 may also be configured to electrically connect the arithmetic circuit 80 to the first detection element 51 and the second detection element 52.

### [Circuit Configuration of Sensor Chip]

As shown in FIG. 8, the arithmetic circuit 80 of the sensor chip 50 is configured to output a signal corresponding to outputs from the first detection element 51 and the second detection element 52. In one example, the arithmetic circuit 80 is configured to output a signal corresponding to an output voltage of the first detection element 51 (hereinafter referred to as a “first output voltage”) and an output voltage of the second detection element 52 (hereinafter referred to as a “second output voltage”). In one example, the arithmetic circuit 80 includes a bias circuit 81, a subtractor circuit 82, an analog front end (hereinafter referred to as an “AFE 83”), and a signal processing circuit 84. Furthermore, the configuration of the arithmetic circuit 80 can be changed arbitrarily.

The bias circuit 81 is electrically connected individually to both the first detection element 51 and the second detection element 52. The bias circuit 81 is electrically connected to a terminal 63 (refer to FIG. 5), which serves as a power supply terminal. The bias circuit 81 receives the first output voltage and the second output voltage separately. The bias circuit 81 is configured to suppress fluctuations in output voltages caused by power supply fluctuations and temperature fluctuations in the first output voltage and the second output voltage, for example. The bias circuit 81 is configured to output the first output voltage and the second output voltage to the subtractor circuit 82.

The subtractor circuit 82 is electrically connected to the bias circuit 81. The subtractor circuit 82 generates an output signal with an influence of magnetic fields external to the sensor chip 50 removed based on the first output voltage and the second output voltage input from the bias circuit 81. In one example, the subtractor circuit 82 is configured to calculate the difference between the first output voltage and the second output voltage.

The AFE 83 electrically connects the subtractor circuit 82 and the signal processing circuit 84. The AFE 83 is configured to adjust an analog signal output as an output signal from the subtractor circuit 82, for example. Therefore, the AFE 83 may also be referred to as a signal adjustment circuit. The AFE 83 may be formed of an amplifier, a sample-and-hold (S/H) circuit, a filter, etc.

The signal processing circuit 84 is configured to convert an analog signal into a digital signal. The signal processing circuit 84 is electrically connected to the terminal 64 (refer to FIG. 7). The signal processing circuit 84 is configured to convert an output signal input from the AFE 83 into a digital signal and output it to the terminal 64.

As such, in the sensor chip 50, the first detection element 51 and the second detection element 52 detect the magnetic field generated by the current flowing through the detection pattern 43. The arithmetic circuit 80 is configured to output a signal corresponding to a value of a current flowing through the detection pattern 43 (the wiring pattern 30) based on the difference between the first output voltage and the second output voltage.

### Application Examples of Semiconductor Device

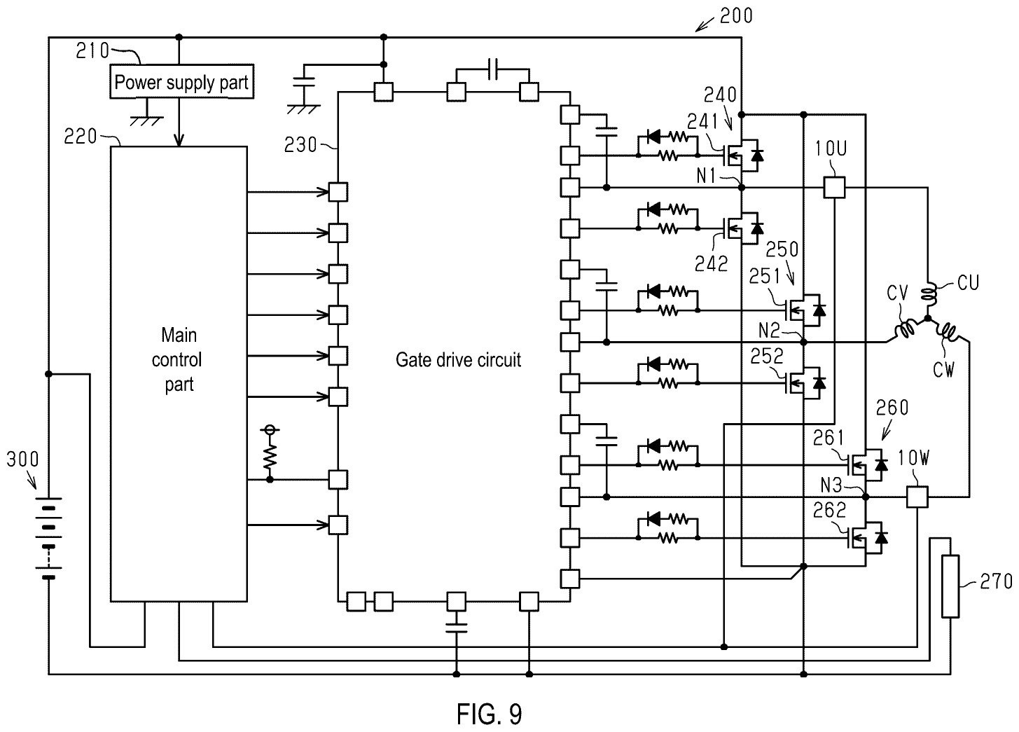

The semiconductor device 10 of the first embodiment may be applied to an inverter device 200 as shown in FIG. 9, for example. The schematic configuration of this inverter device 200 is described.

As shown in FIG. 9, the inverter device 200 is configured to control a current supplied to a U-phase coil CU, a V-phase coil CV, and a W-phase coil CW of a three-phase brushless motor, for example. As a three-phase brushless motor, it is applied to products that requires a relatively high current, such as air conditioners, home appliances, etc. Herein, a current of 10 A or more, for example, is supplied to the three-phase brushless motor. Furthermore, depending on the product applied, a current of 20 A or more, for example, may be supplied to the three-phase brushless motor.

The inverter device 200 is configured to convert a direct current of a DC power supply 300 into a three-phase alternating current. The inverter device 200 mainly comprises a power supply part 210, a main control part 220, a gate drive circuit 230, a U-phase arm part 240, a V-phase arm part 250, a W-phase arm part 260, a temperature sensor 270, and two semiconductor devices 10U, 10W.

The U-phase arm part 240 includes a pair of switching elements 241, 242 connected in series to each other. The V-phase arm part 250 includes a pair of switching elements 251, 252 connected in series to each other. The W-phase arm part 260 includes a pair of switching elements 261, 262 connected in series to each other. As these switching elements 241, 242, 251, 252, 261, 262, transistors such as SiMOSFET (Metal-Oxide-Semiconductor Field-Effect Transistor), IGBT (Insulated Gate Bipolar Transistor), SiCMOSFET, etc. are used.

The power supply part 210 is electrically connected to a positive electrode of a DC power supply 300 and the main control part 220. The power supply part 210 is configured to convert a voltage from the DC power supply 300 to an operating voltage of the main control part 220. The power supply part 210 includes, for example, a DC/DC converter and a linear regulator (LDO: Low Dropout).

The main control part 220 is configured to operate with an operating voltage input from the power supply part 210. The main control part 220 is electrically connected to the gate drive circuit 230, the temperature sensor 270, and the semiconductor devices 10U, 10W. The main control part 220 is configured to control the gate drive circuit 230 based on information related to a three-phase brushless motor and information related to the U-phase arm part 240, the V-phase arm part 250, and the W-phase arm part 260, for example. Herein, the information related to the three-phase brushless motor includes, for example, a rotational position of a motor rotor. The information related to the U-phase arm part 240, the V-phase arm part 250, and the W-phase arm part 260 includes, for example, a temperature of at least one of the U-phase arm part 240, the V-phase arm part 250, and the W-phase arm part 260, an amount of current supplied to the U-phase arm part 240, and an amount of current supplied to the W-phase arm part 260. The above temperature is obtained based on detection information from the temperature sensor 270, for example. The amount of current supplied to the U-phase arm part 240 is obtained based on detection information from the semiconductor device 10U, for example. The amount of current supplied to the W-phase arm part 260 is obtained based on detection information from the semiconductor device 10W, for example. Furthermore, the temperature sensor 270 may also be used to detect an ambient temperature of the inverter device 200.

The gate drive circuit 230 is electrically connected to a positive electrode and a negative electrode of the DC power supply 300. The gate drive circuit 230 is electrically connected to a gate of each of the switching elements 241, 242 of the U-phase arm part 240, the switching elements 251, 252 of the V-phase arm part 250, and the switching elements 261, 262 of the W-phase arm part 260. The gate drive circuit 230 is configured to generate a gate drive signal based on a control signal from the main control part 220 and then output it to the gate of each of the switching elements 241, 242 of the U-phase arm part 240, the switching elements 251, 252 of the V-phase arm part 250, and the switching elements 261, 262 of the W-phase arm part 260.

A drain of the switching element 241 of the U-phase arm part 240, a drain of the switching element 251 of the V-phase arm part 250, and a drain of the switching element 261 of the W-phase arm part 260 are electrically connected to a positive electrode of the DC power supply 300. A source of the switching element 242 of the U-phase arm part 240, a source of the switching element 252 of the V-phase arm part 250, and a source of the switching element 262 of the W-phase arm part 260 are electrically connected to a negative electrode of the DC power supply 300.

A node N1 between the source of the switching element 241 and the drain of the switching element 242 of the U-phase arm part 240 is electrically connected to the U-phase coil CU. A node N2 between the source of the switching element 251 and the drain of the switching element 252 of the V-phase arm part 250 is electrically connected to the V-phase coil CV. A node N3 between the source of the switching element 261 and the drain of the switching element 262 of the W-phase arm part 260 is electrically connected to the W-phase coil CW.

The semiconductor device 10U is provided as part of a U-phase current path between the node N1 and the U-phase coil CU. The semiconductor device 10U is provided to output information on detecting an amount of current supplied to the U-phase arm part 240, i.e., an amount of current flowing through the U-phase current path, to the main control part 220.

The semiconductor device 10W is provided as part of a W-phase current path between the node N3 and the W-phase coil CW. The semiconductor device 10W is provided to output information on detecting an amount of current supplied to the W-phase arm part 260, i.e., an amount of current flowing through the W-phase current path, to the main control part 220.

In the inverter device 200 having such a configuration, on/off of the switching elements 241, 242, 251, 252, 261, 262 are controlled by a predetermined energization method based on the gate drive signal from the gate drive circuit 230. The energization methods include sine-wave drive and square-wave drive, for example. In the case of sine-wave drive, an improvement in the motor efficiency of the three-phase brushless motor can be achieved. In the case of square-wave drive, a reduction in the switching loss of the switching elements 241, 242, 251, 252, 261, 262 can be achieved.

### [Part of Wiring Configuration of Inverter Device]

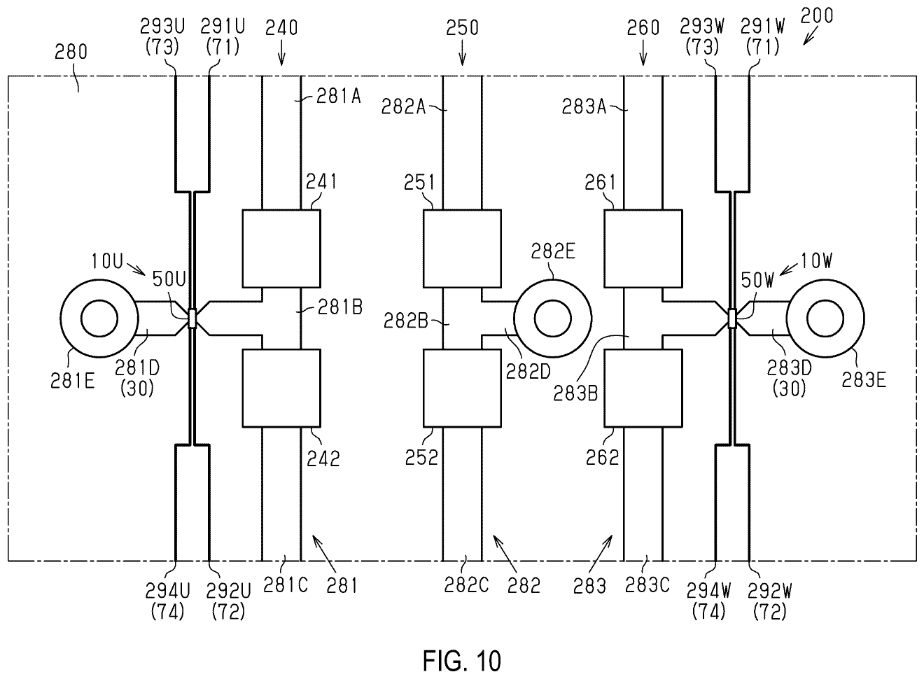

FIG. 10 shows an example of planar structures of the wiring configuration of the U-phase arm part 240, the V-phase arm part 250, and the W-phase arm part 260 of the inverter device 200.

As shown in FIG. 10, the inverter device 200 includes a substrate 280, and a U-phase wiring 281, a V-phase wiring 282, and a W-phase wiring 283 provided on the substrate 280. The substrate 280 is formed of, for example, glass epoxy resin.

The U-phase wiring 281 is connected to the source and drain of the switching elements 241, 242 of the U-phase arm part 240. The U-phase wiring 281 includes a first wiring part 281A, a second wiring part 281B, and a third wiring part 281C. The first wiring part 281A forms part of a current path that electrically connects the drain of the switching element 241 and the positive electrode of the DC power supply 300 (refer to FIG. 9). The second wiring part 281B forms a current path that electrically connects the source of the switching element 241 and the drain of the switching element 242. The third wiring part 281C forms part of a current path that electrically connects the source of the switching element 242 and the negative electrode of the DC power supply 300.

The U-phase wiring 281 includes a fourth wiring part 281D, which forms a node N1 (refer to FIG. 9) in the second wiring part 281B and forms part of a current path that electrically connects the node N1 and the coil CU (refer to FIG. 9). The fourth wiring part 281D is connected to a land pattern 281E. A U-phase connection terminal (not shown) is bonded to the land pattern 281E by, for example, soldering.

The V-phase wiring 282 is connected to the source and drain of the switching elements 251, 252 of the V-phase arm part 250. The V-phase wiring 282 includes a first wiring part 282A, a second wiring part 282B, and a third wiring part 282C. The first wiring part 282A forms part of a current path that electrically connects the drain of the switching element 251 and the positive electrode of the DC power supply 300. The second wiring part 282B forms a current path that electrically connects the source of the switching element 251 and the drain of the switching element 252. The third wiring part 282C forms part of a current path that electrically connects the source of the switching element 252 and the negative electrode of the DC power supply 300.

The V-phase wiring 282 includes a fourth wiring part 282D, which forms a node N2 (refer to FIG. 9) in the second wiring part 282B and forms part of a current path that electrically connects the node N2 and the coil CV (refer to FIG. 9). The fourth wiring part 282D is connected to a land pattern 282E. A V-phase connection terminal (not shown) is bonded to the land pattern 282E by, for example, soldering.

The W-phase wiring 283 is connected to the source and drain of the switching elements 261, 262 of the W-phase arm part 260. The W-phase wiring 283 includes a first wiring part 283A, a second wiring part 283B, and a third wiring part 283C. The first wiring part 283A forms part of a current path that electrically connects the drain of the switching element 261 and the positive electrode of the DC power supply 300. The second wiring part 283B forms a current path that electrically connects the source of the switching element 261 and the drain of the switching element 262. The third wiring part 283C forms part of a current path that electrically connects the source of the switching element 262 and the negative electrode of the DC power supply 300.

The W-phase wiring 283 includes a fourth wiring part 283D, which forms a node N3 (refer to FIG. 9) in the second wiring part 283B and forms part of a current path that electrically connects the node N3 to the coil CW (refer to FIG. 9). The fourth wiring part 283D is connected to a land pattern 283E. A W-phase connection terminal (not shown) is bonded to the land pattern 283E by, for example, soldering.

Although not shown, the substrate 280 is provided with a U-phase gate wiring, a V-phase gate wiring, and a W-phase gate wiring.

The U-phase gate wiring includes a first gate wiring electrically connected to the gate of the switching element 241 of the U-phase arm part 240 and a second gate wiring electrically connected to the gate of the switching element 242. These gate wirings are electrically connected to the gate drive circuit 230.

The V-phase gate wiring includes a first gate wiring electrically connected to the gate of the switching element 251 of the V-phase arm part 250 and a second gate wiring electrically connected to the gate of the switching element 252. These gate wirings are electrically connected to the gate drive circuit 230.

The W-phase gate wiring includes a first gate wiring electrically connected to the gate of the switching element 261 of the W-phase arm part 260 and a second gate wiring electrically connected to the gate of the switching element 262. These gate wirings are electrically connected to the gate drive circuit 230.

The configurations of the semiconductor devices 10U, 10W are the same as the configuration of semiconductor device 10. That is, the semiconductor device 10U is provided including the substrate 280 and the fourth wiring part 281D of the U-phase wiring 281. The semiconductor device 10W is provided including the substrate 280 and the fourth wiring part 283D of the W-phase wiring 283. The configurations of these semiconductor devices 10U, 10W are the same as each other. Herein, the substrates 280 of the semiconductor devices 10U, 10W correspond to the substrate 20 of the semiconductor device 10 (refer to FIG. 1), and the fourth wiring parts 281D, 283D of the semiconductor devices 10U, 10W correspond to the wiring pattern 30 of the semiconductor device 10 (refer to FIG. 1). Therefore, the fourth wiring parts 281D, 283D include the first pattern 41, the second pattern 42, and the detection pattern 43, similar to the wiring pattern 30 (all refer to FIG. 4).

The sensor chip 50U of the semiconductor device 10U is mounted on the substrate 280 so as to cross the fourth wiring part 281D. Although not shown, the sensor chip 50U is mounted on the substrate 280 so as to cross the detection pattern 43 of the fourth wiring part 281D in its width direction. The sensor chip 50U is electrically connected to the main control part 220. More specifically, the substrate 280 is provided with sensor patterns 291U to 294U corresponding to the sensor chip 50U. The sensor patterns 291U to 294U correspond to the first to fourth sensor patterns 71 to 74. The sensor chip 50U is mounted on the sensor patterns 291U to 294U. The sensor patterns 291U to 294U are electrically connected to the main control part 220 (refer to FIG. 9), for example. Therefore, the sensor chip 50U is electrically connected to the main control part 220 through the sensor patterns 291U to 294U. The sensor chip 50U is configured to output a signal corresponding to an amount of current flowing through the detection pattern 43 of the fourth wiring part 281D to the main control part 220.

The sensor chip 50W of the semiconductor device 10W is mounted on the substrate 280 so as to cross the fourth wiring part 283D. Although not shown, the sensor chip 50W is mounted on the substrate 280 so as to cross the detection pattern 43 of the fourth wiring part 283D in its width direction. The sensor chip 50W is electrically connected to the main control part 220. More specifically, the substrate 280 is provided with sensor patterns 291W to 294W corresponding to the sensor chip 50W. The sensor patterns 291W to 294W correspond to the first to fourth sensor patterns 71 to 74. The sensor chip 50W is mounted on the sensor patterns 291W to 294W. The sensor patterns 291W to 294W are electrically connected to the main control part 220, for example. Therefore, the sensor chip 50W is electrically connected to the main control part 220 through the sensor patterns 291W to 294W. The sensor chip 50W is configured to output a signal corresponding to an amount of current flowing through the detection pattern 43 of the fourth wiring part 283D to the main control part 220.

Furthermore, the inverter device 200 may include the semiconductor device 10 provided in part of a V-phase current path between a node N2 and the V-phase coil CV. This semiconductor device 10 is provided to output information on detecting an amount of current flowing through the V-phase current path to the main control part 220. The sensor chip 50 of the semiconductor device 10 is mounted on the substrate 280 so as to cross the fourth wiring part 282D. Although not shown, the sensor chip 50 is mounted on the substrate 280 so as to cross the detection pattern 43 of the fourth wiring part 282D in its width direction. The sensor chip 50 is electrically connected to the main control part 220 through the first to fourth sensor patterns 71 to 74 provided around the fourth wiring part 282D. The sensor chip 50 is configured to output a signal corresponding to an amount of current flowing through the detection pattern 43 of the fourth wiring part 282D to the main control part 220. As such, by providing the semiconductor device 10 in each of the U-phase current path, the V-phase current path, and the W-phase current path, the current supplied to each of the U-phase coil CU, the V-phase coil CV, and the W-phase coil CW can be detected.

Herein, a current of 10 A or more, for example, is supplied to the U-phase coil CU, the V-phase coil CV, and the W-phase coil CW of the three-phase brushless motor. Therefore, a current of 10 A or more, for example, flows through each of the U-phase wiring 281, the V-phase wiring 282, and the W-phase wiring 283. As a result, a current of 10 A or more, for example, flows through each of the detection pattern 43 of the U-phase wiring 281 and the detection pattern 43 of the W-phase wiring 283. Therefore, the semiconductor devices 10U, 10W are used when a current flowing through the detection pattern 43 is 10 A or more. Furthermore, when a current of 20 A or more, for example, is supplied to the U-phase coil CU, the V-phase coil CV, and the W-phase coil CW of the three-phase brushless motor, it can be said that the semiconductor devices 10U, 10W are used when a current flowing through the detection pattern 43 is 20 A or more.

Additionally, in the inverter device 200, the semiconductor device 10 may be provided in a power supply wiring that connects the U-phase arm part 240, the V-phase arm part 250, and the W-phase arm part 260 to the positive electrode of the DC power supply 300. That is, this semiconductor device 10 may be configured to detect a current flowing through the power supply wiring. Additionally, in the inverter device 200, the semiconductor device 10 may be provided in a ground wiring that connects the U-phase arm part 240, the V-phase arm part 250, and the W-phase arm part 260 to the negative electrode of the DC power supply 300. That is, this semiconductor device 10 may be configured to detect a current flowing through the ground wiring. As such, the current supplied to the V-phase current path can be detected by using the semiconductor devices 10U, 10W, and the semiconductor device 10 provided in the power supply wiring or the ground wiring.

Furthermore, when the semiconductor device 10 is provided in the power supply wiring or the ground wiring in the inverter device 200 shown in FIG. 9, if the semiconductor device 10 is provided in two of the U-phase current path, the V-phase current path, and the W-phase current path, the current supplied to the U-phase coil CU, the V-phase coil CV, and the W-phase coil CW can be detected.

### [Function of the First Embodiment]

The function of the semiconductor device 10 in the first embodiment is described.

Generally, current sensors using a magnetic detection element such as a Hall element include the following first configuration and second configuration. In the first configuration, the current sensor is configured to electrically connect a first separation pattern and a second separation pattern which are wiring patterns separated from each other. That is, in the first configuration, a Hall element provided in the current sensor detects a magnetic field generated by a current drawn into the current sensor by drawing the current flowing through the wiring pattern into the current sensor. In the second configuration, the wiring pattern is formed in a rectangular shape by a forward path part, a return path part, and a connecting part that connects the forward path part and the return path part, and the current sensor is disposed opposite to the forward path part and the return path part. The current sensor is configured to detect a magnetic field based on a current flowing through the forward path part and a magnetic field based on a current flowing through the return path part.

However, in the first configuration, since the current flowing through the wiring pattern is drawn into the current sensor, an insulation structure provided in the current sensor becomes larger when a large current flows. In the second configuration, since the wiring pattern needs to be formed in a rectangular shape, a space required for the wiring pattern to detect the current flowing through the wiring pattern becomes larger.

In this regard, in the first embodiment, the sensor chip 50 is mounted on the first substrate surface 20S of the substrate 20 so as to cross the detection pattern 43 of the wiring pattern 30 extending in the Y direction in the X direction. The sensor chip 50 can detect the magnetic field based on a current flowing through the detection pattern 43 in a non-contact state with respect to the detection pattern 43. Thus, even if a large current flows through the detection pattern 43, a size increase of the insulation structure of the sensor chip 50 can be suppressed. Additionally, the wiring pattern 30 only needs to include the detection pattern 43, and does not need to be formed in a rectangular shape in order to detect the current flowing through the wiring pattern 30 as in the second configuration. The wiring pattern 30 of the first embodiment extends linearly in the Y direction. Therefore, an increase in the space of the wiring pattern 30 required for detecting the current flowing through the wiring pattern 30 can be suppressed.

### [Effects of the First Embodiment]

According to the semiconductor device 10 of the first embodiment, the following effects can be obtained.

(1-1) The semiconductor device 10 includes a substrate 20 including a first substrate surface 20S and a second substrate surface 20R opposite to the first substrate surface 20S, a wiring pattern 30 provided on the first substrate surface 20S, and a sensor chip 50 used to detect a current flowing through the wiring pattern 30. The wiring pattern 30 includes a detection pattern 43 having a predetermined width. The sensor chip 50 is mounted on the first substrate surface 20S in a state of being disposed to cross the detection pattern 43. The sensor chip 50 includes a first detection element 51 and a second detection element 52 as detection elements that detect a magnetic field generated by a current flowing through the detection pattern 43.

According to this configuration, the wiring pattern 30 does not need to be in a rectangular shape in order to detect the current flowing through the wiring pattern 30, and therefore an increase in the space of the wiring pattern 30 required for detecting the current flowing through the wiring pattern 30 can be suppressed. Therefore, an improvement in a flexibility of a layout of the wiring pattern 30 can be achieved.

(1-2) The first detection element 51 and the second detection element 52 are provided on both sides of the detection pattern 43 in a width direction in the X direction with respect to the detection pattern 43 in a plan view. The first detection element 51 and the second detection element 52 are disposed opposite to each other in the X direction via the detection pattern 43.

According to this configuration, the first detection element 51 and the second detection element 52 can each detect each of magnetic fields in mutually opposite directions among magnetic fields generated by a current flowing through the detection pattern 43. Meanwhile, an external magnetic field is superimposed as a positive value in one direction of the magnetic field among the above directions of the magnetic field and superimposed as a negative value in the other direction of the magnetic field among the above directions of the magnetic field. As a result, an output voltage of the first detection element 51 and an output voltage of the second detection element 52 become values different from each other due to the influence of the external magnetic field. Therefore, for example, the external magnetic field can be removed by the difference between the output voltage of the first detection element 51 and the output voltage of the second detection element 52. Thus, the magnetic field of the detection pattern 43 with the influence of the external magnetic field removed can be detected based on the first detection element 51 and the second detection element 52.

(1-3) In the Z direction, which is a thickness direction of the substrate 20, a gap GP is provided between the sensor chip 50 and the detection pattern 43.

According to this configuration, the influence of heat generated by the detection pattern 43 on the sensor chip 50 can be suppressed.

(1-4) A distance DA between the first and second detection elements 51, 52 and the detection pattern 43 in the Z direction is smaller than a thickness TC of the detection pattern 43.

According to this configuration, both the first detection element 51 and the second detection element 52 can be brought closer to the detection pattern 43. Thus, the magnetic flux entering both the first detection element 51 and the second detection element 52 approaches perpendicular to the first detection element 51 and the second detection element 52, and therefore an improvement in a detection accuracy of the first detection element 51 and the second detection element 52 can be achieved.

(1-5) The wiring pattern 30 includes a first pattern 41 extending in the Y direction, a second pattern 42 provided at a position spaced apart from the first pattern 41 in the Y direction and extending in the Y direction, and a detection pattern 43 provided between the first pattern 41 and the second pattern 42 and connects the first pattern 41 and the second pattern 42. The first pattern 41 has a first width W1, which is a length in the X direction, in the plan view. The second pattern 42 has a second width W2, which is a length in the X direction. The detection pattern 43 has a connection width WC, which is a length in the X direction. The connection width WC is narrower than the first width W1 and the second width W2. The sensor chip 50 is mounted on the first substrate surface 20S in a state of being disposed to cross the detection pattern 43.

According to this configuration, since the current is concentrated in the detection pattern 43, a magnetic force generated by the current flowing through the detection pattern 43 becomes stronger. Thus, it becomes easier to detect the magnetic field of the detection pattern 43 by the first detection element 51 and the second detection element 52. Moreover, as a connection width WC of the detection pattern 43 becomes narrower, a length of the sensor chip 50 in the X direction that crosses the detection pattern 43 can be reduced. Thus, a miniaturization of the sensor chip 50 can be achieved.

(1-6) A length LC of the detection pattern 43 in the Y direction is shorter than a length L1 of the first pattern 41 in the Y direction and a length L2 of the second pattern 42 in the Y direction.

According to this configuration, since the length LC of the narrow width detection pattern 43 in the Y direction is made shorter than the lengths L1, L2 of the wide width first pattern 41 and second pattern 42 in the Y direction, an increase in electrical resistance of the wiring pattern 30 can be suppressed.

(1-7) The first pattern 41 includes a first portion 41A having a first width W1 and a second portion 41B that narrows from the first portion 41A toward the detection pattern 43.

According to this configuration, when an external force is applied to the substrate 20, for example, breakage of the first pattern 41 can be suppressed.

(1-8) The second pattern 42 includes a first portion 42A having a second width W2 and a second portion 42B that narrows from the first portion 42A toward the detection pattern 43.

According to this configuration, when an external force is applied to the substrate 20, for example, breakage of the second pattern 42 can be suppressed.

(1-9) The sensor chip 50 includes a plurality of terminals 61 to 64. The sensor chip 50 is mounted in a space SP provided in the X direction of the detection pattern 43 such that the plurality of terminals 61 to 64 are disposed in the space SP.

According to this configuration, since the plurality of terminals 61 to 64 are disposed in the space SP formed depending on shapes of the first pattern 41, the second pattern 42, and the detection pattern 43 of the wiring pattern 30, separately providing a space for disposing the plurality of terminals 61 to 64 becomes unnecessary. As a result, the space formed by the wiring pattern 30 on the first substrate surface 20S can be effectively utilized.

(1-10) When viewed from the Y direction, the plurality of terminals 61 to 64 are disposed inside outer edges of the first pattern 41 and the second pattern 42.

According to this configuration, since the plurality of terminals 61 to 64 are disposed in the space SP formed due to the connection width WC of the detection pattern 43 being narrower than the first width W1 of the first pattern 41 and the second width W2 of the second pattern 42, providing a space outside of the wiring pattern 30 in the X direction for disposing the plurality of terminals 61 to 64 becomes unnecessary. As a result, the space formed by the wiring pattern 30 on the first substrate surface 20S can be effectively utilized. Thus, wiring patterns other than the wiring pattern 30 on the first substrate surface 20S of the substrate 20 can be disposed closer to the wiring pattern 30, and therefore an improvement in a flexibility of a layout of the wiring patterns other than the wiring pattern 30 can be achieved.

(1-11) The semiconductor device 10 includes first to fourth sensor patterns 71 to 74, which are provided on the first substrate surface 20S and to which the plurality of terminals 61 to 64 are individually connected. Upper surfaces 71S to 74S of each of the first to fourth sensor patterns 71 to 74 are positioned closer to the first substrate surface 20S than an upper surface 43S of the detection pattern 43.

According to this configuration, the sensor chip 50 can be brought closer to the upper surface 43S of the detection pattern 43. That is, the first detection element 51 and the second detection element 52 can be brought closer to the detection pattern 43. Thus, the magnetic flux entering both the first detection element 51 and the second detection element 52 approaches perpendicular to the first detection element 51 and the second detection element 52, and therefore an improvement in a detection accuracy of the first detection element 51 and the second detection element 52 can be achieved.

(1-12) The substrate 20 includes a first base material 21, a second base material 22 positioned closer to the second substrate surface 20R than the first base material 21, and a third base material 23 positioned closer to the second substrate surface 20R than the second base material 22 and including the second substrate surface 20R. A first heat dissipation pattern 32 is provided between the first base material 21 and the second base material 22. A second heat dissipation pattern 33 is provided between the second base material 22 and the third base material 23. A third heat dissipation pattern 34 is provided on the second substrate surface 20R.

According to this configuration, heat of the first wiring pattern 31 moves to the first to third heat dissipation patterns 32 to 34. Therefore, since an improvement in the heat dissipation performance of the wiring pattern 30 can be achieved, an increase of the temperature of the wiring pattern 30 can be suppressed.

(1-13) Each of the first to third heat dissipation patterns 32 to 34 has a heat dissipation width WP larger than both the first width W1 and the second width W2.

According to this configuration, since an area of each of the first to third heat dissipation patterns 32 to 34 can be increased, an improvement in a heat dissipation performance of the wiring pattern 30 based on the first to third heat dissipation patterns 32 to 34 can be achieved.

(1-14) The semiconductor device 10 is used when a current flowing through the detection pattern is 10 A or more.

According to this configuration, when a large current of 10 A or more flows through the detection pattern 43, a magnetic field of the detection pattern 43 is detected by the sensor chip 50, which is not in contact with the detection pattern 43, and therefore a size increase of the insulation structure within the sensor chip 50 can be suppressed.

(1-15) A package structure of the sensor chip 50 is WLCSP (Wafer Level Chip Scale Package).

According to this configuration, compared with the case where the package structure of the sensor chip 50 is, for example, SOP (Small Outline Package), miniaturization of the sensor chip 50 can be achieved. Thus, a space of the substrate 20 for detecting the current of the wiring pattern 30 can be reduced.

(1-16) The sensor chip 50 includes a semiconductor substrate 55 and a semiconductor layer 56 provided on the semiconductor substrate 55. The first detection element 51 and the second detection element 52 are provided in the semiconductor layer 56. The semiconductor layer 56 is disposed closer to the detection pattern 43 than the semiconductor substrate 55. The plurality of terminals 61 to 64 are provided on a side of the semiconductor layer 56 that is opposite to the semiconductor substrate 55.

According to this configuration, when the sensor chip 50 is mounted on the first substrate surface 20S, the first detection element 51 and the second detection element 52 in the sensor chip 50 are positioned close to the wiring pattern 30. Therefore, an improvement in a detection accuracy of a magnetic field of the detection pattern 43 by the first detection element 51 and the second detection element 52 can be achieved.

(1-17) The plurality of terminals 61 to 64 are disposed on both sides of the detection pattern 43 in the X direction, which is a width direction of the detection pattern 43.

According to this configuration, the sensor chip 50 is supported by the plurality of terminals 61 to 64 at positions spaced apart in the X direction with respect to the first substrate surface 20S. Therefore, compared to a configuration where the sensor chip 50 is supported on only one side in the X direction with respect to the first substrate surface 20S, detachment of the plurality of terminals 61 to 64 from the first substrate surface 20S when an external force is applied to the sensor chip 50 can be suppressed. Thus, the reliability of mounting the sensor chip 50 on the first substrate surface 20S can be enhanced.

(1-18) The sensor chip 50 includes an arithmetic circuit 80 configured to output a signal corresponding to outputs from the first detection element 51 and the second detection element 52.

According to this configuration, compared to the case where a chip for the arithmetic circuit 80 is provided separately from the sensor chip 50, the number of components can be reduced.

(1-19) The arithmetic circuit 80 is configured to output a signal corresponding to a value of a current flowing through the wiring pattern 30 based on a difference between an output voltage of the first detection element 51 and an output voltage of the second detection element 52.

According to this configuration, the external magnetic field can be removed by the difference between the output voltage of the first detection element 51 and the output voltage of the second detection element 52. Thus, the magnetic field of the detection pattern 43 with the influence of the external magnetic field removed can be detected based on the output voltage of the first detection element 51 and the output voltage of the second detection element 52.

(1-20) The first detection element 51, the second detection element 52, and the arithmetic circuit 80 are provided in the semiconductor layer 56.

According to this configuration, a current path between the first detection element 51, the second detection element 52, and the arithmetic circuit 80 becomes shorter, and therefore an inductance caused by this current path can be reduced. Thus, a value of a current flowing through the detection pattern 43 can be accurately calculated by the arithmetic circuit 80.

(1-21) The first detection element 51 and the second detection element 52 are Hall elements.

According to this configuration, compared to the case where the first detection element 51 and the second detection element 52 are MR elements, MI elements, etc., a reduction in the cost of the sensor chip 50 can be achieved.

### Second Embodiment

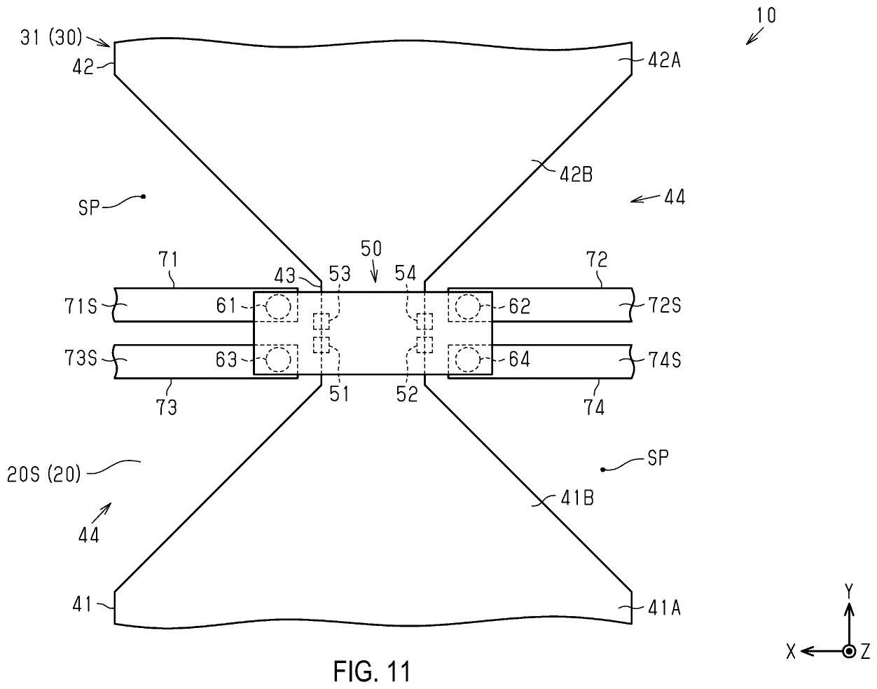

Referring to FIG. 11, the configuration of the semiconductor device 10 of a second embodiment is described. In the semiconductor device 10 of the second embodiment, compared with the semiconductor device 10 of the first embodiment, the difference lies in the number of detection elements. In the following, components common to the semiconductor device 10 of the first embodiment are denoted by the same reference numerals, and descriptions thereof are omitted. FIG. 11 shows an enlarged planar structure of the sensor chip 50 and its periphery in the semiconductor device 10 of the second embodiment.

As shown in FIG. 11, the sensor chip 50 of the semiconductor device 10 of the second embodiment further includes a third detection element 53 and a fourth detection element 54. The third detection element 53 and the fourth detection element 54 are, for example, Hall elements. Furthermore, the third detection element 53 and the fourth detection element 54 are not limited to Hall elements, and magnetic impedance elements (MI elements) or magnetoresistive effect elements (MR elements) may also be used. The first to fourth detection elements 51 to 54 may be the same type of magnetic detection elements as each other. In the second embodiment, each of the first to fourth detection elements 51 to 54 is a Hall element.

The third detection element 53 and the fourth detection element 54 are disposed closer to the second pattern 42 than the first detection element 51 and the second detection element 52 in a plan view. The third detection element 53 and the fourth detection element 54 are positioned at a same position as each other in the Y direction and are spaced apart from each other in the X direction.

The third detection element 53 is disposed alongside the first detection element 51 in the Y direction. In one example, the third detection element 53 is disposed at a position overlapping the first detection element 51 when viewed from the Y direction. In the second embodiment, the third detection element 53 is disposed at a same position as the first detection element 51 in the X direction. That is, the third detection element 53 is disposed to cross one end edge of the detection pattern 43 in the X direction in the plan view.

The fourth detection element 54 is disposed alongside the second detection element 52 in the Y direction. In one example, the fourth detection element 54 is disposed at a position overlapping the second detection element 52 when viewed from the Y direction. In the second embodiment, the fourth detection element 54 is disposed at a same position as the second detection element 52 in the X direction. That is, the fourth detection element 54 is disposed to cross the other end edge of the detection pattern 43 in the X direction in the plan view.

Furthermore, although not shown, the third detection element 53 and the fourth detection element 54 are disposed at a same position in the Z direction. The third detection element 53 and the fourth detection element 54 are disposed at a same position as the first detection element 51 and the second detection element 52 in the Z direction. The third detection element 53 and the fourth detection element 54 are provided in the semiconductor layer 56 (refer to FIG. 7) of the sensor chip 50. The third detection element 53 and the fourth detection element 54 are electrically connected to the arithmetic circuit 80 (refer to FIG. 8) of the sensor chip 50.

In the semiconductor device 10 with such a configuration, the arithmetic circuit 80 is configured to output a signal corresponding to a value of a current flowing through the wiring pattern 30 based on output voltages of the first to fourth detection elements 51 to 54. More specifically, the arithmetic circuit 80 calculates a difference between a first output voltage, which is the output voltage of the first detection element 51, and a second output voltage, which is the output voltage of the second detection element 52. As a result, a first signal with the influence of external magnetic fields on the first detection element 51 and the second detection element 52 removed is generated. The arithmetic circuit 80 calculates a difference between a third output voltage, which is the output voltage of the third detection element 53, and a fourth output voltage, which is the output voltage of the fourth detection element 54. As a result, a second signal with the influence of external magnetic fields on the third detection element 53 and the fourth detection element 54 removed is generated. Then, the arithmetic circuit 80 generates an output signal based on an average value of the first signal and the second signal. This output signal corresponds to a value of a current flowing through the wiring pattern 30.

### [Effects of the Second Embodiment]

According to the semiconductor device 10 of the second embodiment, the following effects can be obtained.

(2-1) The sensor chip 50 includes a third detection element 53 disposed alongside the first detection element 51 in the Y direction, which is the direction in which the detection pattern 43 extends, and a fourth detection element 54 disposed at a same position as the third detection element 53 in the Y direction and alongside the second detection element 52. According to this configuration, a current flowing through the detection pattern 43 can be detected by the first to fourth detection elements 51 to 54, and therefore an improvement in detection accuracy can be achieved.

(2-2) The sensor chip 50 includes an arithmetic circuit 80 which is configured to output a signal corresponding to outputs from the first detection element 51, the second detection element 52, the third detection element 53, and the fourth detection element 54. The arithmetic circuit 80 is configured to output a signal corresponding to a value of a current flowing through the detection pattern 43 based on an average value of the difference between the output voltage of the first detection element 51 and the output voltage of the second detection element 52 and the difference between the output voltage of the third detection element 53 and the output voltage of the fourth detection element 54.

According to this configuration, the variation in detection by the first detection element 51 and the second detection element 52 and the variation in detection by the third detection element 53 and the fourth detection element 54 can be leveled out, and therefore a signal with small variations in detection by these first to fourth detection elements 51 to 54 can be output.

### Third Embodiment

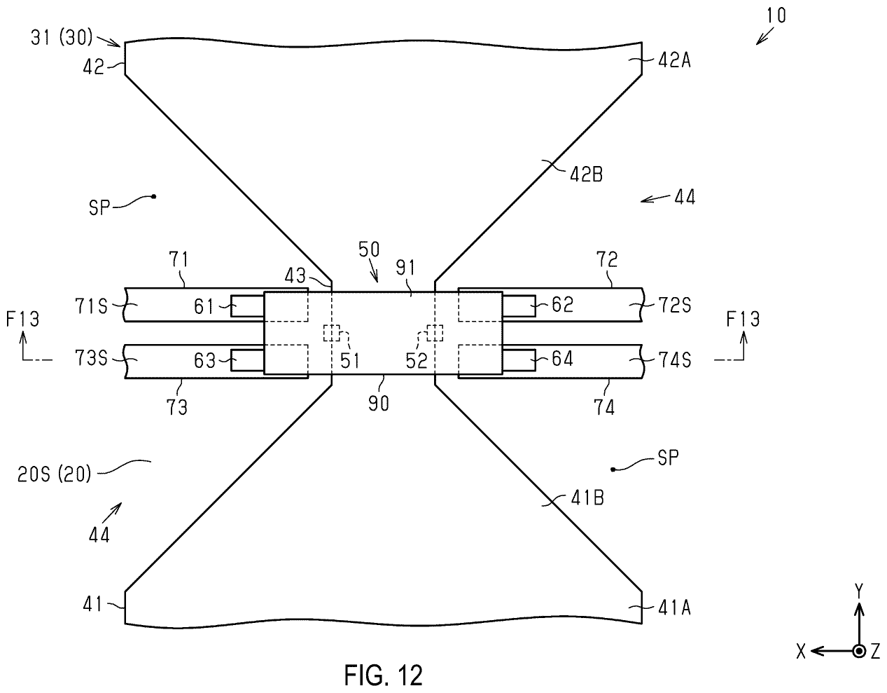

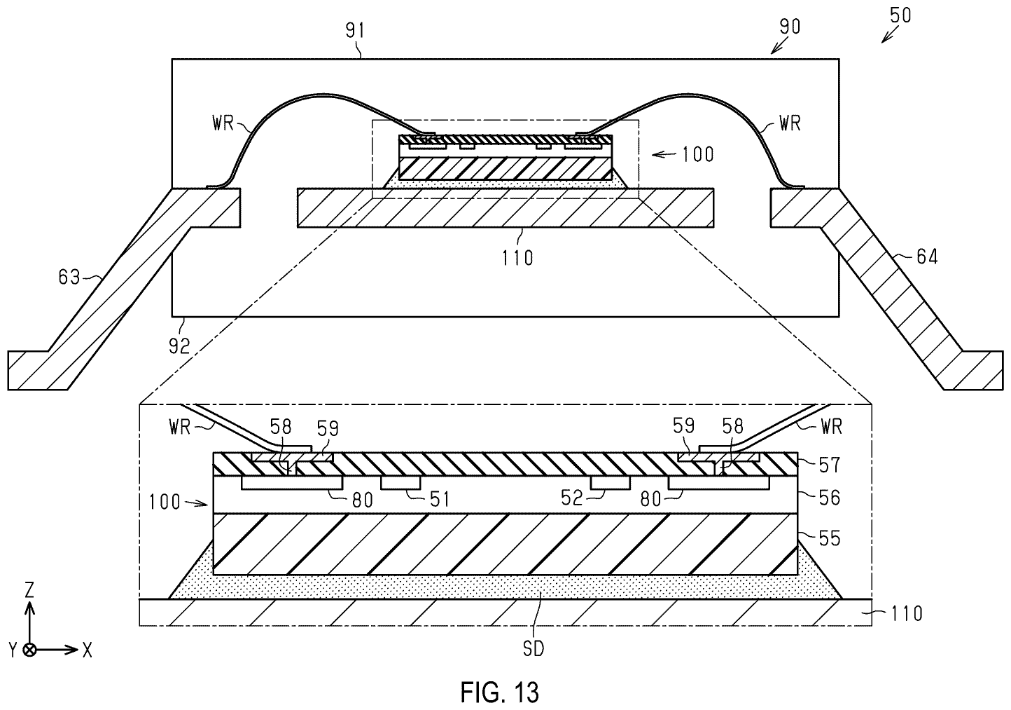

Referring to FIG. 12 and FIG. 13, the semiconductor device 10 of a third embodiment is described. In the semiconductor device 10 of the third embodiment, compared with the semiconductor device 10 of the first embodiment, the main difference lies in a package structure of the sensor chip 50. In the following, components common to the first embodiment are denoted by the same reference numerals, and descriptions thereof are omitted.

FIG. 12 schematically shows an enlarged planar structure of the sensor chip 50 and its periphery in the semiconductor device 10 of the third embodiment. FIG. 13 schematically shows a cross-sectional structure of the sensor chip 50 cut along a line F13-F13 in FIG. 12.

As shown in FIG. 12 and FIG. 13, a package structure of the sensor chip 50 is SOP instead of WLCSP. Therefore, the sensor chip 50 includes a sealing resin 90. Additionally, the terminals 61 to 64 of the sensor chip 50 are formed of leads instead of solder bumps.

As shown in FIG. 12, the terminals 61 to 64 protrude from the sealing resin 90 in the X direction. The terminals 61 to 64 are bonded to the corresponding first to fourth sensor patterns 71 to 74 by, for example, solder. The terminals 61 to 64 are disposed in a recess 44 of the wiring pattern 30. The terminals 61 to 64 are disposed in a trapezoidal space SP formed by the first pattern 41, the second pattern 42, and the detection pattern 43 of the wiring pattern 30 in a plan view.

As shown in FIG. 13, the sealing resin 90 includes a first sealing surface 91 and a second sealing surface 92 opposite to the first sealing surface 91. The sealing resin 90 is formed of an insulating material. The insulating material may be, for example, an epoxy resin. The first sealing surface 91 faces a same side as the first substrate surface 20S of the substrate 20. The second sealing surface 92 is a surface facing the wiring pattern 30.

The sensor chip 50 includes a sensor element 100 and a die pad 110 provided within the sealing resin 90. The sensor element 100 is formed of a semiconductor substrate 55, a semiconductor layer 56, an insulating layer 57 (refer to FIG. 8), and a wiring 58 (refer to FIG. 8). That is, the sealing resin 90 seals the semiconductor substrate 55 and the semiconductor layer 56. Both the first detection element 51 and the second detection element 52 are provided in the semiconductor layer 56, similar to the first embodiment. The die pad 110 holds the sensor element 100. The die pad 110 is formed of a non-magnetic metal material such as Al, Cu, etc. The die pad 110 is in a form of a flat plate with its thickness direction in the Z direction. The sensor element 100 is bonded to the die pad 110 by a conductive bonding material SD such as solder paste, silver (Ag) paste, etc.

In the example shown in FIG. 13, the sensor element 100 is disposed closer to the first sealing surface 91 relative to the die pad 110. Therefore, both the first detection element 51 and the second detection element 52 are disposed closer to the first sealing surface 91 than the second sealing surface 92 of the sealing resin 90 in the Z direction. The semiconductor layer 56 of the sensor element 100 is provided with four pads 59. These pads 59 are electrically connected to a wiring 58. That is, these pads 59 are electrically connected to the arithmetic circuit 80 through the wiring 58.

The four pads 59 are individually electrically connected to the corresponding terminals 61 to 64 by a plurality of wires WR. Each wire WR is a bonding wire formed of a conductive material such as Al, Cu, Ag, Au, etc. Each wire WR is sealed by the sealing resin 90. Furthermore, according to the semiconductor device 10 of the third embodiment, effects similar to those of the first embodiment can be obtained.

### Modified Examples

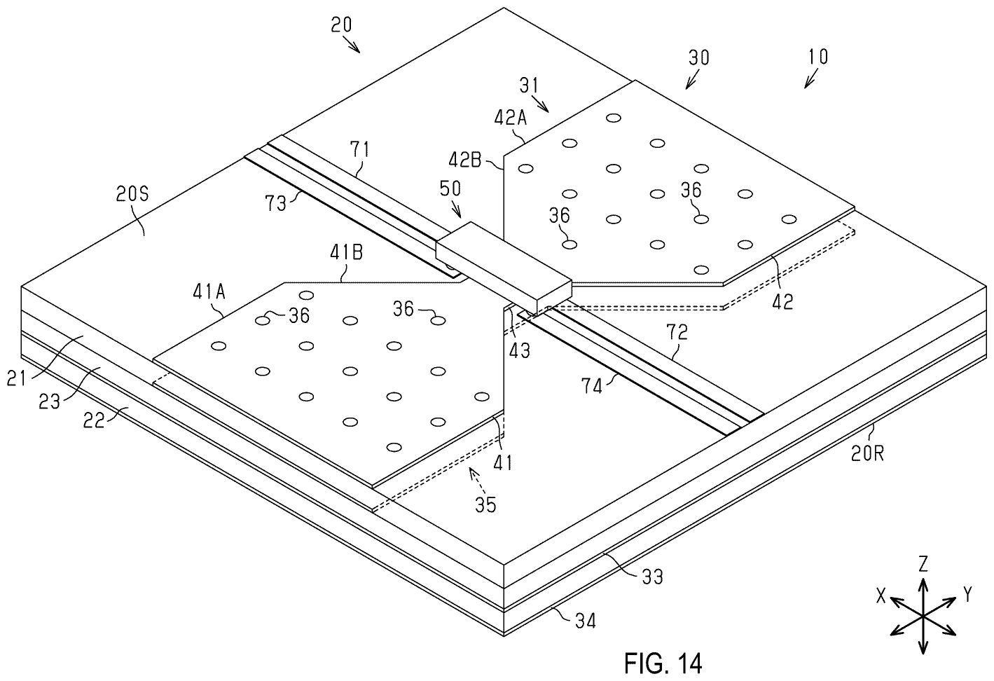

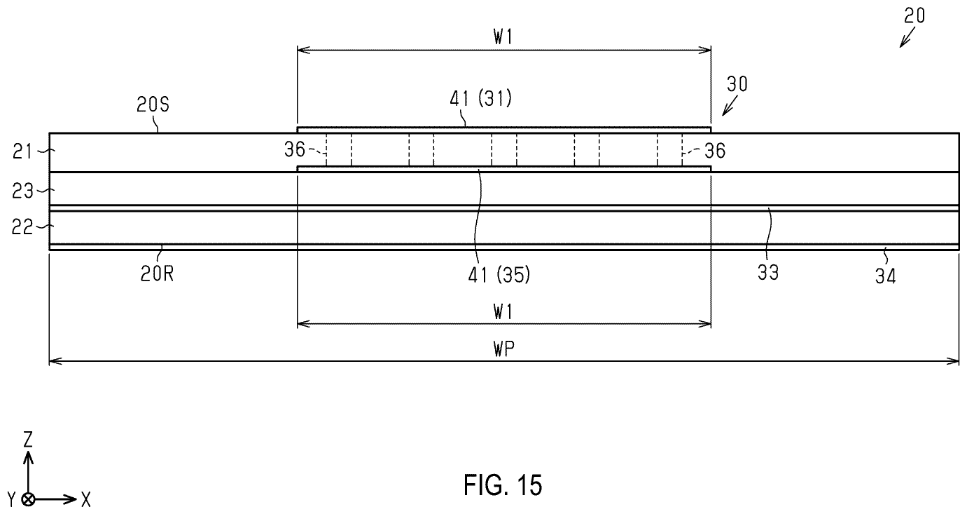

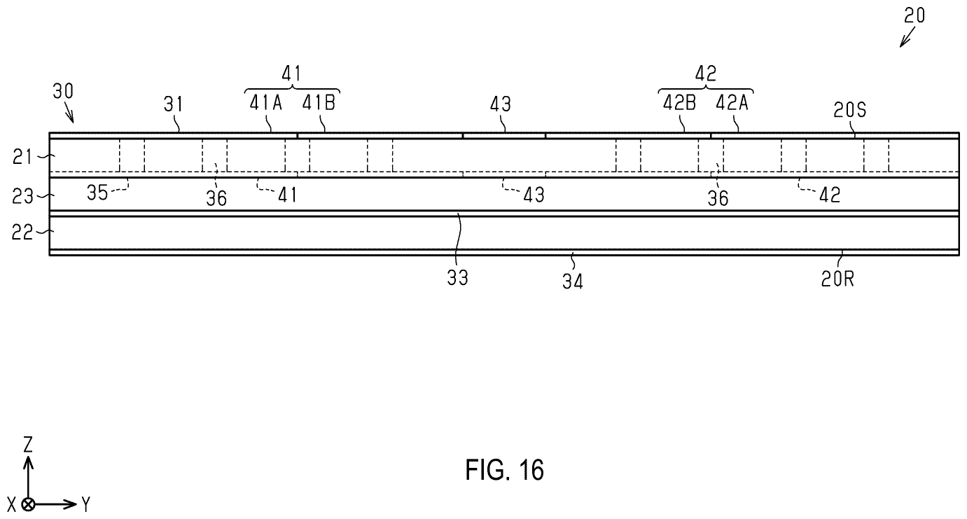

The above embodiments can be modified and implemented as follows. Additionally, the above embodiments and the following modified examples can be implemented in combination with each other to the extent that there is no technical contradiction.
In each embodiment, the wiring pattern 30 may be modified as shown in FIGS. 14 to FIG. 16. FIG. 14 schematically shows a perspective structure of the semiconductor device 10 in the modified example. FIG. 15 schematically shows a side structure of the substrate 20 of the semiconductor device 10 in FIG. 14. FIG. 16 schematically shows a structure of the substrate 20 when viewed from a different direction than that of FIG. 15.

As shown in FIGS. 14 to FIG. 16, the wiring pattern 30 of the modified example includes a second wiring pattern 35 instead of the first heat dissipation pattern 32. The second wiring pattern 35 is provided between the first base material 21 and the third base material 23. In one example, the second wiring pattern 35 is disposed opposite to the first wiring pattern 31 in the Z direction. In one example, the second wiring pattern 35 has the same size and shape as the first wiring pattern 31. Therefore, the second wiring pattern 35 includes a first pattern 41, a second pattern 42, and a detection pattern 43, similar to the first wiring pattern 31. The second wiring pattern 35 is electrically connected to the first wiring pattern 31.

The wiring pattern 30 includes at least one through hole 36 that connects the first wiring pattern 31 and the second wiring pattern 35 in the Z direction. The through hole 36 penetrates the first base material 21 in the Z direction.

Herein, the through hole 36 is a connecting conductor that includes a metal layer provided on an inner surface of a through via penetrating the first base material 21. The metal layer is formed of a conductive material such as Al, Cu, Ti, TiN, W, etc. In one example, the metal layer is formed of the same material as the first wiring pattern 31 and the second wiring pattern 35. Furthermore, the metal layer of the through hole 36 may be provided to fill the through via.

In the example shown in FIG. 14 and FIG. 15, the wiring pattern 30 includes a plurality of through holes 36. The plurality of through holes 36 are provided in the first pattern 41 and the second pattern 42. Meanwhile, the plurality of through holes 36 are not provided in the detection pattern 43.

The plurality of through holes 36 are disposed spaced apart in the X direction and the Y direction in the first portion 41A of the first pattern 41. In one example, the plurality of through holes 36 are disposed in a matrix (e.g., 5×3) in a plan view. One of the through holes 36 is provided in the second portion 41B of the first pattern 41. This through hole 36 is provided at a center in the X direction and the Y direction of the second portion 41B.

The plurality of through holes 36 are disposed spaced apart in the X direction and the Y direction in the first portion 42A of the second pattern 42. In one example, the plurality of through holes 36 are disposed in a matrix (e.g., 5×3) in the plan view. One of the through holes 36 is provided in the second portion 42B of the second pattern 42. This through hole 36 is provided at a center in the X direction and the Y direction of the second portion 42B.

The through hole 36 is configured to connect the first wiring pattern 31 and the second wiring pattern 35 and is disposed spaced apart in the Z direction from the second heat dissipation pattern 33 and the third heat dissipation pattern 34. Therefore, the second heat dissipation pattern 33 and the third heat dissipation pattern 34 are insulated from the first wiring pattern 31 and the second wiring pattern 35. Furthermore, the size and shape of the second heat dissipation pattern 33 and the third heat dissipation pattern 34 are similar to those in the first embodiment.

According to the modified example of the semiconductor device 10 shown in FIGS. 14 to FIG. 16, the following effects can be obtained.

The substrate 20 is a multilayer substrate that includes a laminated structure in which the first base material 21 and the second base material 22 are laminated. The first base material 21 includes the first substrate surface 20S. The wiring pattern 30 includes the first wiring pattern 31 provided on the first base material 21 and the second wiring pattern 35 provided between the first base material 21 and the third base material 23 and electrically connected to the first wiring pattern 31. Each of the first wiring pattern 31 and the second wiring pattern 35 includes the first pattern 41, the second pattern 42, and the detection pattern 43.

According to this configuration, a current flowing through the wiring pattern 30 branches and flows into the first wiring pattern 31 and the second wiring pattern 35. As a result, an amount of current flowing through each of the first wiring pattern 31 and the second wiring pattern 35 is reduced, thereby reducing an amount of heat generated by the first wiring pattern 31 and the second wiring pattern 35. Thus, the temperature of the wiring pattern 30 can be inhibited from becoming excessively high.

The wiring pattern 30 includes at least one through hole 36 that penetrates the first base material 21 in the Z direction and connects the first wiring pattern 31 and the second wiring pattern 35.

According to this configuration, heat can be dissipated to the outside of the wiring pattern 30 through the through hole 36. Therefore, an improvement in the heat dissipation performance of the wiring pattern 30 can be achieved, and therefore the temperature of the wiring pattern 30 can be further inhibited from increasing.

The through hole 36 is not provided in the detection pattern 43 and is provided in at least one of the first pattern 41 and the second pattern 42.

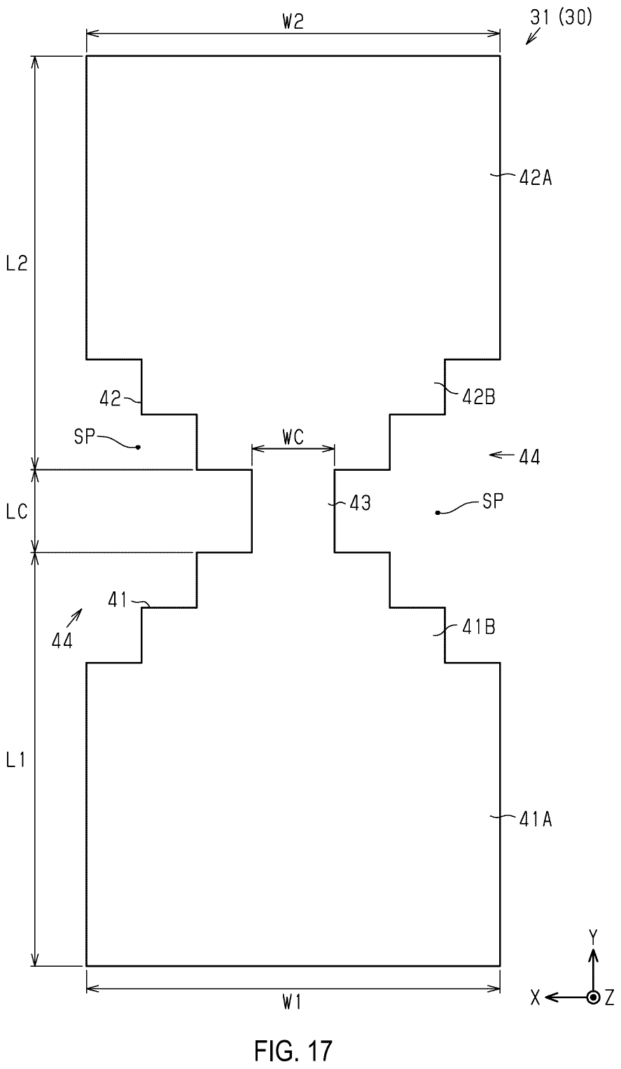

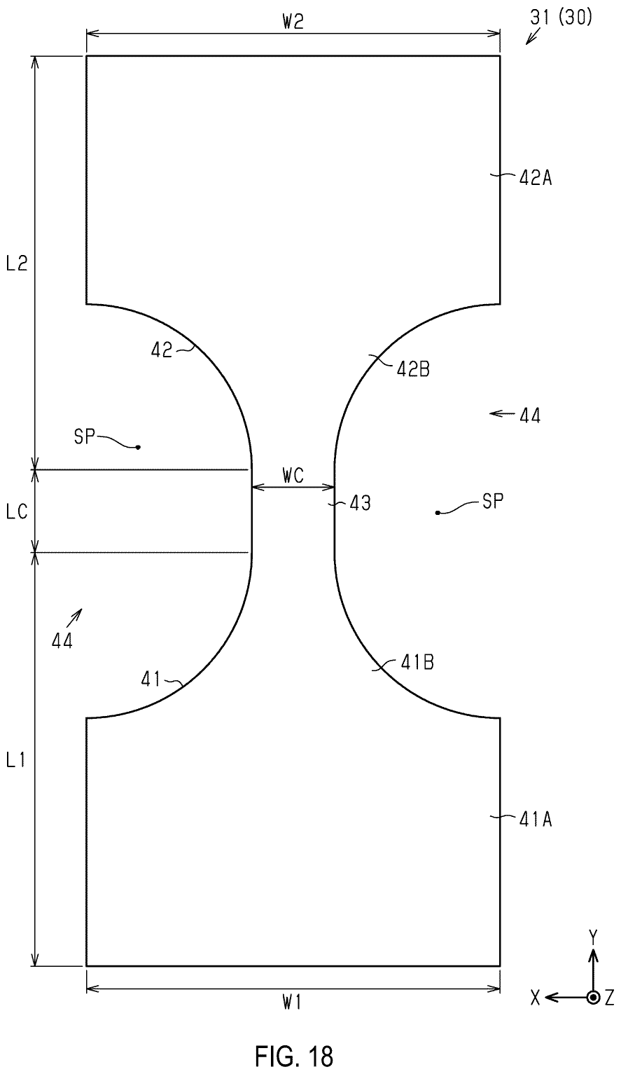

According to this configuration, the through hole 36 is not provided in the detection pattern 43, and therefore the influence of the magnetic field caused by the current flowing through the through hole 36 on the first detection element 51 and the second detection element 52 can be suppressed. Moreover, by providing the through holes 36 in the first pattern 41 and the second pattern 42, which have a larger area than the detection pattern 43, the number of through holes 36 can be increased. Thus, an improvement in the heat dissipation performance of the wiring pattern 30 can be achieved.
In the modified examples shown in FIGS. 14 to FIG. 16, the second wiring pattern 35 may have a different shape from the first wiring pattern 31.
In the modified examples shown in FIGS. 14 to FIG. 16, the arrangement position of the through hole 36 can be changed arbitrarily. In one example, the through hole 36 of the second portion 41B of the first pattern 41 may be omitted. In one example, the through hole 36 of the second portion 42B of the second pattern 42 may be omitted.
In the modified examples shown in FIGS. 14 to FIG. 16, the configuration of the substrate 20 can be changed arbitrarily. In one example, the substrate 20 may have a laminated structure of the first base material 21 and the second base material 22. In this case, the second heat dissipation pattern 33 may be omitted. In one example, the substrate 20 may be formed of the first base material 21. In this case, in one example, both the second heat dissipation pattern 33 and the third heat dissipation pattern 34 may be omitted. That is, the first wiring pattern 31 is provided on the first substrate surface 20S of the substrate 20, and the second wiring pattern 35 is provided on the second substrate surface 20R.
In the modified examples shown in FIGS. 14 to FIG. 16, a third wiring pattern may be provided between the second base material 22 and the third base material 23 of the substrate 20 in place of the second heat dissipation pattern 33. The third wiring pattern has the same size and shape as the first wiring pattern 31 and the second wiring pattern 35. In this case, the through hole 36 is provided to penetrate both the first base material 21 and the third base material 23. Therefore, the first wiring pattern 31, the second wiring pattern 35, and the third wiring pattern are electrically connected to each other by the through hole 36. Meanwhile, the third wiring pattern is insulated from the third heat dissipation pattern 34.
In each embodiment, the shape of the wiring pattern 30 in the plan view can be changed arbitrarily. FIG. 17 and FIG. 18 respectively show modified examples of the wiring pattern 30. FIG. 17 and FIG. 18 schematically show planar structures of the wiring pattern 30.

As shown in FIG. 17, in the wiring pattern 30 of the first modified example, the second portion 41B of the first pattern 41 may be provided in a stepped shape. A width of the second portion 41B decreases toward the detection pattern 43. The second portion 42B of the second pattern 42 may be provided in a stepped shape, similarly. A width of the second portion 42B decreases toward the detection pattern 43.

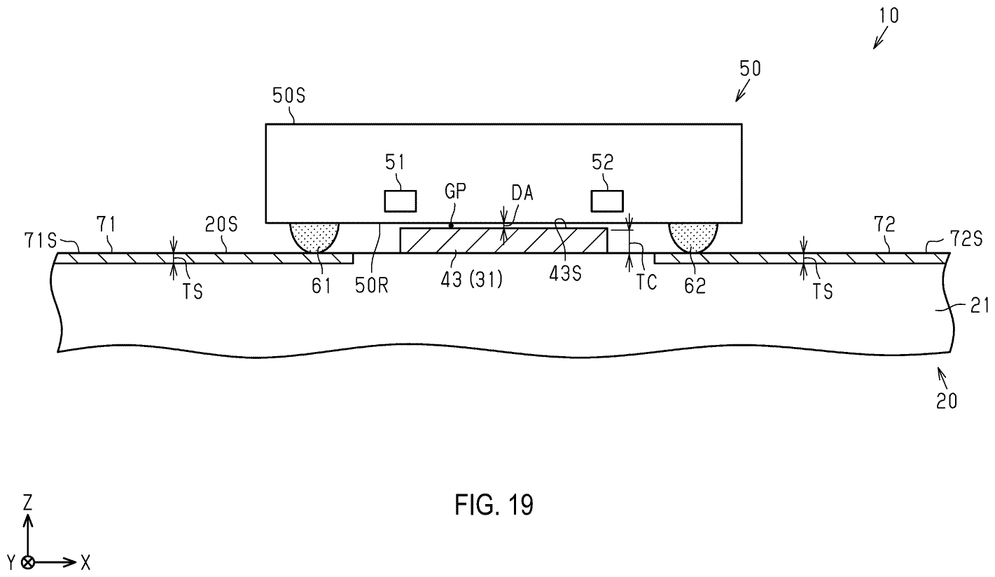

As shown in FIG. 18, in the wiring pattern 30 of the second modified example, the second portion 41B of the first pattern 41 may be provided in a curved shape. The second portion 42B of the second pattern 42 may be provided in a curved shape.
In each embodiment, the second portion 41B may be omitted from the first pattern 41. In this case, the detection pattern 43 is connected to the first portion 41A of the first pattern 41. Additionally, in each embodiment, the second portion 42B may be omitted from the second pattern 42. In this case, the detection pattern 43 is connected to the first portion 42A of the second pattern 42.
In each embodiment, a length LC of the detection pattern 43 in the Y direction may be equal to or greater than a length L1 of the first pattern 41 in the Y direction and a length L2 of the second pattern 42 in the Y direction.
In the first to third embodiments, heat dissipation widths WP of the first to third heat dissipation patterns 32 to 34 can be changed arbitrarily. In one example, the heat dissipation width WP of the first heat dissipation pattern 32 may be equal to or less than a first width W1 of the first pattern 41. In one example, the heat dissipation width WP of the first heat dissipation pattern 32 may be equal to or less than a second width W2 of the second pattern 42. In one example, the heat dissipation width WP of the second heat dissipation pattern 33 may be equal to or less than the first width W1 of the first pattern 41. In one example, the heat dissipation width WP of the second heat dissipation pattern 33 may be equal to or less than the second width W2 of the second pattern 42. In one example, the heat dissipation width WP of the third heat dissipation pattern 34 may be equal to or less than the first width W1 of the first pattern 41. In one example, the heat dissipation width WP of the third heat dissipation pattern 34 may be equal to or less than the second width W2 of the second pattern 42. Additionally, the heat dissipation widths WP of the first to third heat dissipation patterns 32 to 34 may differ from each other.
In each embodiment, the sensor chip 50 may include one detection element instead of the first detection element 51 and the second detection element 52. In the second embodiment, the sensor chip 50 may include one detection element instead of the first to fourth detection elements 51 to 54. In these cases, the arithmetic circuit 80 of the sensor chip 50 is configured to output a signal corresponding to an output from one detection element.
In each embodiment, the arrangement of the plurality of terminals 61 to 64 can be changed arbitrarily. In one example, the plurality of terminals 61 to 64 may be disposed in a space SP on one side of the detection pattern 43 in the X direction in a plan view.
In each embodiment, the number of terminals of the sensor chip 50 is not limited to four of terminals 61 to 64 and can be changed arbitrarily.
In each embodiment, the plurality of terminals 61 to 64 may be disposed outside the trapezoidal space SP formed by the second portion 41B of the first pattern 41, the detection pattern 43, and the second portion 42B of the second pattern 42 in the X direction.
In each embodiment, a thickness TS of each of the first sensor pattern 71 and the second sensor pattern 72 may be equal to or greater than a thickness of the wiring pattern 30 (the thickness TC of the detection pattern 43). Additionally, a thickness of each of the third sensor pattern 73 and the fourth sensor pattern 74 may also be equal to or greater than the thickness of the wiring pattern 30 (the thickness TC of the detection pattern 43).
In the first and second embodiments, the configurations of the first to fourth sensor patterns 71 to 74 can be changed arbitrarily. FIG. 19 is a modified example of the first to fourth sensor patterns 71 to 74, and schematically shows a cross-sectional structure of the sensor chip 50, the substrate 20, the wiring pattern 30, the first sensor pattern 71, and the second sensor pattern 72.

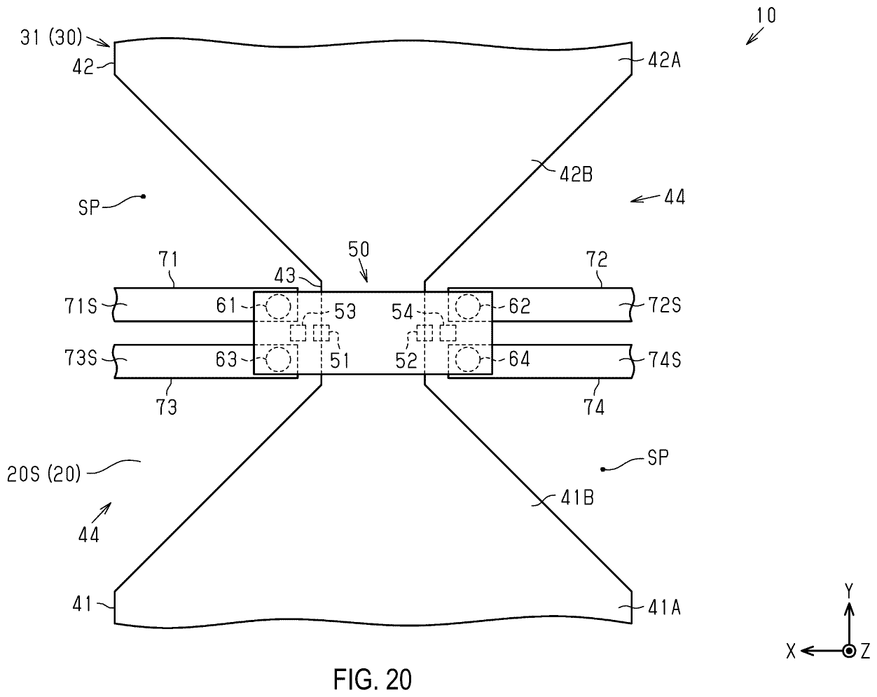

As shown in FIG. 19, the first to fourth sensor patterns 71 to 74 may be provided to be embedded in the substrate 20. In this case, an upper surface 71S of the first sensor pattern 71 and an upper surface 72S of the second sensor pattern 72 may be flush with the first substrate surface 20S. As a result, a gap GP between the sensor chip 50 and the detection pattern 43 in the Z direction becomes smaller than that in the first and second embodiments. That is, when the modified example shown in FIG. 19 is applied to the first embodiment, both the first detection element 51 and the second detection element 52 are disposed closer to the detection pattern 43. As a result, the magnetic field generated by the detection pattern 43 enters so as to approach perpendicular to the detection surfaces of the first detection element 51 and the second detection element 52, and therefore an improvement in the detection accuracy of the magnetic field by the first detection element 51 and the second detection element 52 can be achieved. When the modified example shown in FIG. 19 is applied to the second embodiment, each of the first to fourth detection elements 51 to 54 is disposed closer to the detection pattern 43. As a result, the magnetic field generated by the detection pattern 43 enters so as to approach perpendicular to the detection surfaces of the first to fourth detection elements 51 to 54, and therefore an improvement in the detection accuracy of the magnetic field by the first to fourth detection elements 51 to 54 can be achieved. Furthermore, the first to fourth sensor patterns 71 to 74 of the third embodiment may also be modified similarly to FIG. 19.
In the second embodiment, the arrangement positions of the third detection element 53 and the fourth detection element 54 can be changed arbitrarily. FIG. 20 shows a modified example of the arrangement positions of the third detection element 53 and the fourth detection element 54. FIG. 20 schematically shows an enlarged planar structure of the sensor chip 50 and its periphery in the semiconductor device 10 of the modified example.

As shown in FIG. 20, the third detection element 53 is disposed alongside the first detection element 51 on a side of the first detection element 51 that is opposite to the second detection element 52 in the X direction. The fourth detection element 54 is disposed alongside the second detection element 52 on a side of the second detection element 52 that is opposite to the first detection element 51. The third detection element 53 is disposed at a position overlapping the first detection element 51 when viewed from the X direction. More specifically, the third detection element 53 is disposed at a same position as the first detection element 51 in the Y direction. The fourth detection element 54 is disposed at a position overlapping the second detection element 52 when viewed from the X direction. More specifically, the fourth detection element 54 is disposed at a same position as the second detection element 52 in the Y direction.

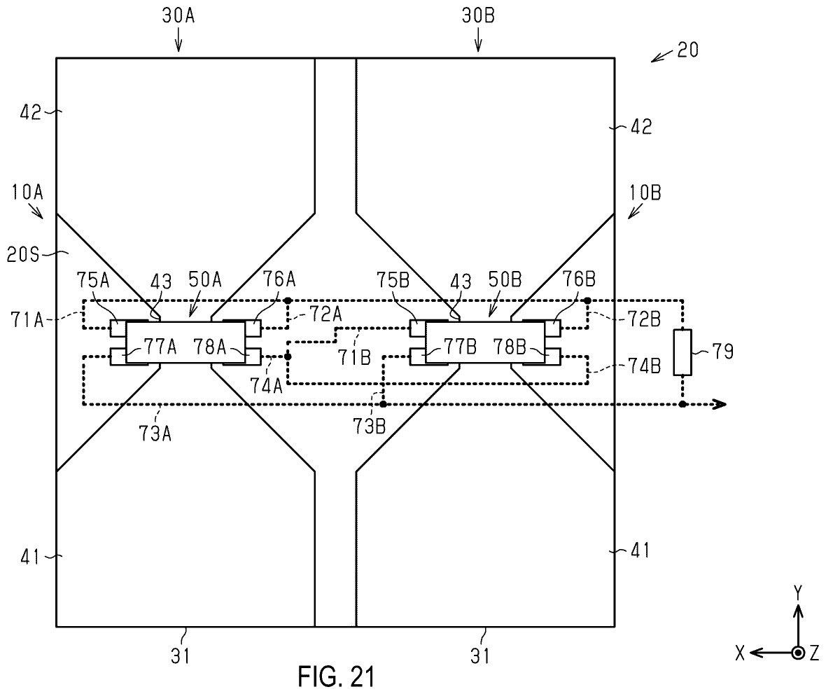

The third detection element 53 is disposed outward from the detection pattern 43 in the X direction. The fourth detection element 54 is disposed outward from the detection pattern 43 in the X direction. Meanwhile, the third detection element 53 and the fourth detection element 54 are disposed within a trapezoidal space SP formed by the second portion 41B of the first pattern 41, the second portion 42B of the second pattern 42, and the detection pattern 43.
In the third embodiment, in the sensor chip 50, the first and second detection elements 51, 52 and the arithmetic circuit 80 may be provided in separate semiconductor layers. In one example, the sensor chip 50 includes a first semiconductor substrate, a first semiconductor layer provided on the first semiconductor substrate, a second semiconductor substrate, and a second semiconductor layer provided on the second semiconductor substrate. The first semiconductor substrate is disposed spaced apart from the second semiconductor substrate. The first detection element 51 and the second detection element 52 are provided in the first semiconductor layer. The arithmetic circuit 80 is provided in the second semiconductor layer. The first detection element 51 and the second detection element 52 are electrically connected to the arithmetic circuit 80 by, for example, wires.
In the third embodiment, the arrangement of the sensor element 100 of the sensor chip 50 can be changed arbitrarily. In one example, the sensor element 100 may be disposed such that the semiconductor layer 56 is closer to the second sealing surface 92 of the sealing resin 90 relative to the semiconductor substrate 55. In this case, the sensor element 100 is mounted on the die pad 110 in a state closer to the second sealing surface 92 relative to the die pad 110. As a result, both the first detection element 51 and the second detection element 52 are disposed closer to the second sealing surface 92 than the first sealing surface 91 of the sealing resin 90 in the Z direction.
In each embodiment, as shown in FIG. 21, two semiconductor devices 10A, 10B may be provided adjacent to each other in the X direction. FIG. 21 schematically shows planar structures of the semiconductor devices 10A, 10B. The semiconductor device 10A includes a substrate 20, a wiring pattern 30A, and a sensor chip 50A. The semiconductor device 10B includes a substrate 20, a wiring pattern 30B, and a sensor chip 50B. As such, the semiconductor devices 10A, 10B include a common substrate 20.

Two wiring patterns 30A, 30B are disposed adjacent to each other in the X direction. Each of the wiring patterns 30A, 30B includes a first pattern 41, a second pattern 42, and a detection pattern 43, similar to each embodiment. The wiring patterns 30A, 30B have the same size and shape as each other.

The sensor chip 50A is mounted on the substrate 20 so as to cross the detection pattern 43 of the wiring pattern 30A in the X direction. The sensor chip 50B is mounted on the substrate 20 so as to cross the detection pattern 43 of the wiring pattern 30B in the X direction. The sensor chips 50A, 50B have the same size and shape as each other.

The substrate 20 is provided with the first to fourth sensor patterns 71A to 74A, 71B to 74B. The first to fourth sensor patterns 71A to 74A are electrically connected to the terminals 61 to 64 of the sensor chip 50A, respectively. The first to fourth sensor patterns 71B to 74B are electrically connected to the terminals 61 to 64 of the sensor chip 50B, respectively. The first to fourth sensor patterns 71A to 74A, 71B to 74B are provided between the second base material 22 and the third base material 23 in place of the second heat dissipation pattern 33 (refer to FIG. 2) of each embodiment.

On the first substrate surface 20S of the substrate 20, first to fourth lands 75A to 78A, 75B to 78B, which are electrically connected to the first to fourth sensor patterns 71A to 74A, 71B to 74B, respectively, are provided. The first to fourth sensor patterns 71A to 74A and the first to fourth lands 75A to 78A are connected by through holes (not shown). The first to fourth sensor patterns 71B to 74B and the first to fourth lands 75B to 78B are connected by through holes (not shown). These through holes penetrate both the first base material 21 and the second base material 22 in the Z direction.

Furthermore, positions of the first to fourth sensor patterns 71A to 74A, 71B to 74B on the substrate 20 in the Z-direction can be changed arbitrarily. Positions of the through holes in the substrate 20 may be changed corresponding to the positions of the first to fourth sensor patterns 71A to 74A, 71B to 74B in the Z-direction. In one example, the first to fourth sensor patterns 71A to 74A, 71B to 74B may be provided on the second substrate surface 20R of the substrate 20.

The third sensor pattern 73A is connected to the third sensor pattern 73B and extends in the X direction. Signals output from the sensor chips 50A, 50B are supplied to the third sensor patterns 73A, 73B. The third sensor patterns 73A, 73B are electrically connected to the main control part 220 (refer to FIG. 9) which is not shown. As such, by connecting the third sensor patterns 73A, 73B, the semiconductor devices 10A, 10B are configured to serially communicate signals from the sensor chips 50A, 50B. In the example shown in FIG. 21, a UART (Universal Asynchronous Receiver Transmitter) is adopted for serial communication.

The fourth sensor pattern 74A, the fourth sensor pattern 74B, and the first sensor pattern 71B are connected to each other. The fourth sensor patterns 74A, 74B and the first sensor pattern 71B form, for example, a ground wiring.

The first sensor pattern 71A, the second sensor pattern 72A, and the second sensor pattern 72B are connected to each other. The first sensor pattern 71A and the second sensor patterns 72A, 72B are connected to the third sensor pattern 73A via a pull-up resistor 79. The first sensor pattern 71A and the second sensor patterns 72A and 72B form, for example, a power supply wiring.

Furthermore, the connection mode of the first to fourth sensor patterns 71A to 74A, 71B to 74B and the sensor chips 50A, 50B can be changed arbitrarily depending on the device to which the semiconductor device 10 is applied. Additionally, the connection mode of the first to fourth sensor patterns 71A to 74A, 71B to 74B and the sensor chips 50A, 50B can be changed arbitrarily depending on terminal configurations of the sensor chips 50A, 50B.

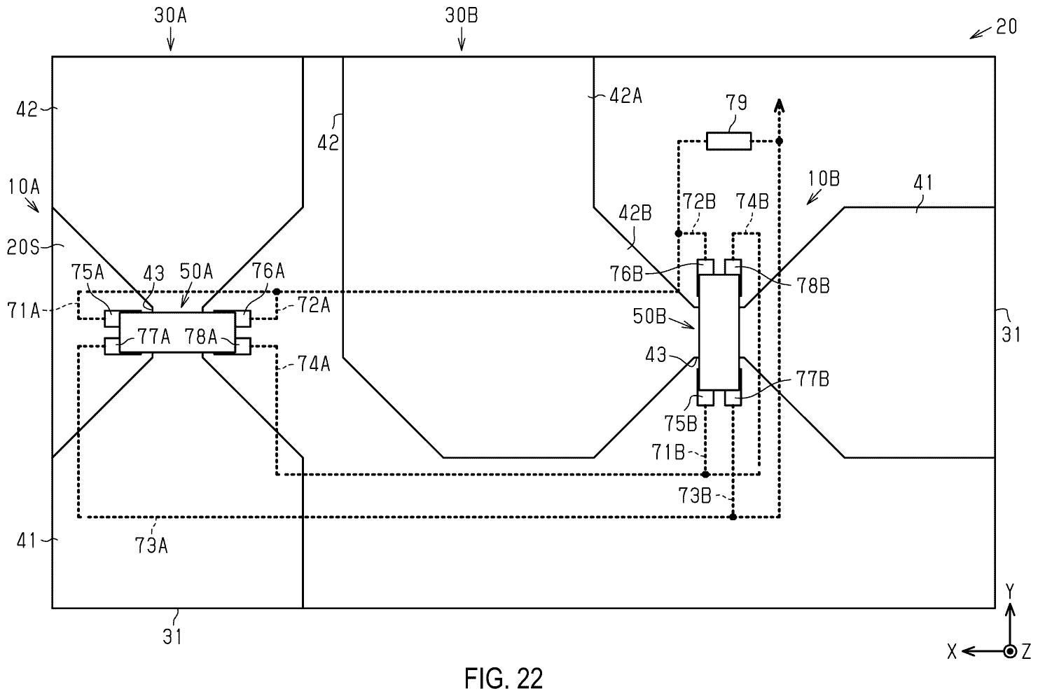

Additionally, shapes of the wiring patterns 30A, 30B in a plan view can be changed arbitrarily. In one example, as shown in FIG. 22, the wiring pattern 30B may have a shape inclined 90° counterclockwise relative to the wiring pattern 30A in a plan view. In this case, the first portion 42A of the second pattern 42 of the wiring pattern 30B extends in the Y direction. Then, the second portion 42B is connected to the first portion 42A in the X direction. Therefore, the second portion 42B extends in the X direction in the plan view. Then, both the detection pattern 43 connected to the second portion 42B and the first pattern 41 connected to the detection pattern 43 extend in the X direction in the plan view. The sensor chip 50B is disposed to be inclined 90° counterclockwise relative to the sensor chip 50A, for example.
In each embodiment, the sensor chip 50 may not include the arithmetic circuit 80. That is, a circuit chip including the arithmetic circuit 80 may be provided separately from the sensor chip 50.
In each embodiment, at least one through hole connecting the first heat dissipation pattern 32 and the second heat dissipation pattern 33 may be provided. The through hole penetrates the third base material 23 in the Z direction. Furthermore, instead of the through hole, at least one through via penetrating the third base material 23 in the Z direction may be provided.

In another example, at least one through hole connecting the first to third heat dissipation patterns 32 to 34 may be provided. The through hole penetrates both the second base material 22 and the third base material 23 in the Z direction. Furthermore, instead of the through hole, at least one through via penetrating both the second base material 22 and the third base material 23 may be provided.

In another example, at least one through hole connecting the second heat dissipation pattern 33 and the third heat dissipation pattern 34 may be provided. The through hole penetrates the second base material 22 in the Z direction. Furthermore, instead of the through hole, at least one through via penetrating the second base material 22 in the Z direction may be provided.
In each embodiment, the configuration of the substrate 20 can be changed arbitrarily. In one example, the substrate 20 may have a laminated structure of the first base material 21 and the second base material 22. In this case, the second heat dissipation pattern 33 may be omitted. In one example, the substrate 20 may be formed of the first base material 21. In this case, in one example, both the second heat dissipation pattern 33 and the third heat dissipation pattern 34 may be omitted. That is, the first wiring pattern 31 is provided on the first substrate surface 20S of the substrate 20, and the first heat dissipation pattern 32 is provided on the second substrate surface 20R. In another example, when the substrate 20 is formed of the first base material 21, the first to third heat dissipation patterns 32 to 34 may be omitted. That is, the first wiring pattern 31 is provided on the first substrate surface 20S of the substrate 20, and no wiring pattern is provided on the second substrate surface 20R.
In each embodiment, the package structure of the sensor chip 50 can be changed arbitrarily. The package structure of the sensor chip 50 may be a QFN (Quad Flat No-Lead Package), DFP (Dual Flat Package), DIP (Dual Inline Package), QFP (Quad Flat Package), SIP (Single Inline Package), SOJ (Small Outline J-leaded Package), or various package structures similar to these.

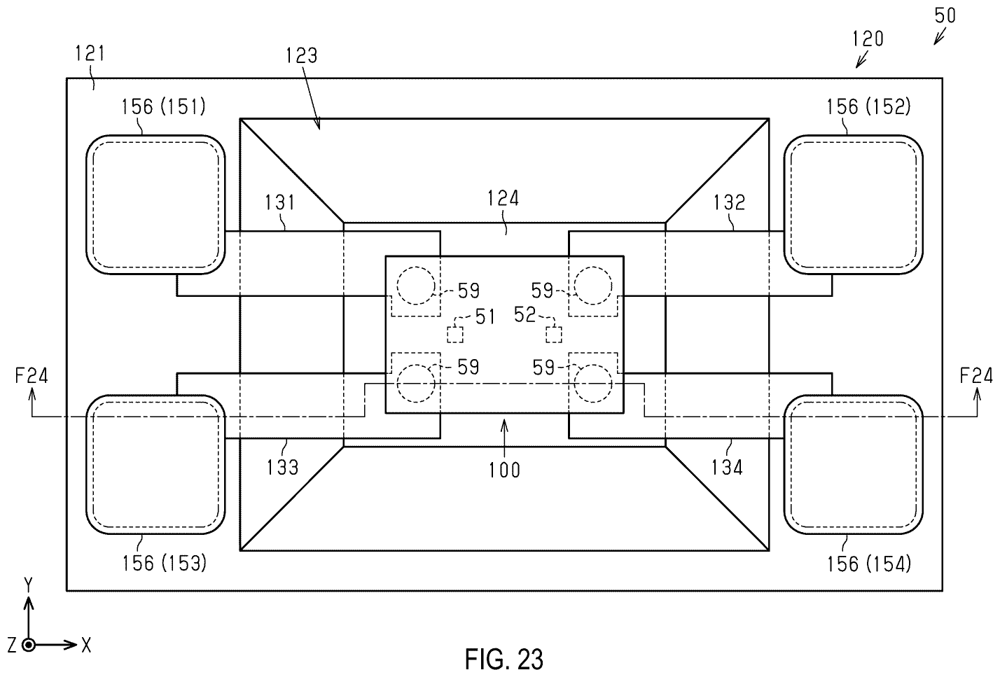

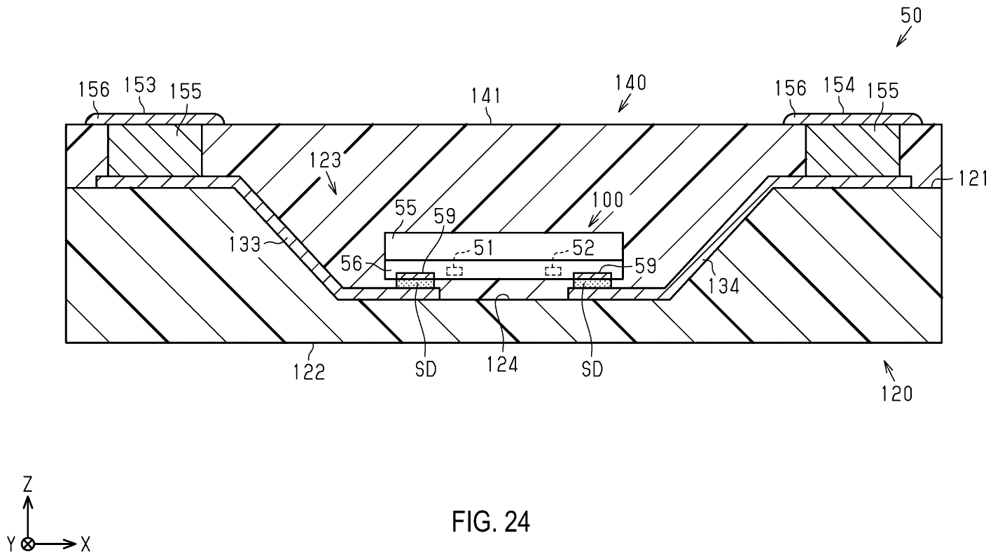

FIG. 23 and FIG. 24 show an example of a modified example of the package structure of the sensor chip 50. FIG. 23 schematically shows a planar structure of the sensor chip 50. FIG. 24 schematically shows a cross-sectional structure of the sensor chip 50 cut along a line F24-F24 in FIG. 23. Furthermore, in FIG. 23, a sealing resin 140, which is described later, is omitted for ease of understanding the figures.

As shown in FIG. 23 and FIG. 24, the sensor chip 50 includes an insulating substrate 120 on which a sensor element 100 is mounted, and first to fourth conductive layers 131 to 134 electrically connected to the sensor element 100.

The insulating substrate 120 is formed of, for example, an epoxy resin. The insulating substrate 120 includes a first substrate surface 121, a second substrate surface 122 opposite to the first substrate surface 121, and a recess 123 that is recessed from the first substrate surface 121 toward the second substrate surface 122. The sensor element 100 is disposed within the recess 123.

The first to fourth conductive layers 131 to 134 are individually electrically connected to four pads 59 of the sensor element 100. More specifically, the four pads 59 of the sensor element 100 are individually bonded to the first to fourth conductive layers 131 to 134 using a conductive bonding material SD. The first to fourth conductive layers 131 to 134 extend from near a center portion of a bottom surface 124 of the recess 123 to a first substrate surface 121 provided on an outer peripheral portion of the insulating substrate 120 beyond the recess 123 in a plan view. The first to fourth conductive layers 131 to 134 are formed of a conductive material such as Al, Cu, Ti, TiN, W, etc.

The sensor element 100 is disposed such that the semiconductor substrate 55 is closer to the bottom surface 124 of the recess 123 relative to the semiconductor layer 56. The sensor element 100 is mounted on portions of the first to fourth conductive layers 131 to 134 provided on the bottom surface 124 by the four pads 59.

The sensor chip 50 includes a sealing resin 140 that seals the sensor element 100 and terminals 151 to 154 individually connected to the first to fourth conductive layers 131 to 134.

The sealing resin 140 fills the recess 123 and covers the first substrate surface 121. The sealing resin 140 is formed of, for example, an epoxy resin. The sealing resin 140 includes a sealing surface 141 that forms a mounting surface of the sensor chip 50.

The terminals 151 to 154 are provided to be exposed from the sealing surface 141. The terminals 151 to 154 include a columnar conductor portion 155 that penetrates a portion of the sealing resin 140 covering the first substrate surface 121 in the Z direction, and a joint portion 156 connected to the columnar conductor portion 155 and protruding from the sealing surface 141.

The columnar conductor portion 155 of the terminal 151 is connected to a portion of the first conductive layer 131 provided on the first substrate surface 121. The columnar conductor portion 155 of the terminal 152 is connected to a portion of the second conductive layer 132 provided on the first substrate surface 121. The columnar conductor portion 155 of the terminal 153 is connected to a portion of the third conductive layer 133 provided on the first substrate surface 121. The columnar conductor portion 155 of the terminal 154 is connected to a portion of the fourth conductive layer 134 provided on the first substrate surface 121. When the sensor chip 50 is mounted on the first substrate surface 20S of the substrate 20 (refer to FIG. 1), the joint portions 156 of the terminals 151 to 154 are individually mounted on the first to fourth sensor patterns 71 to 74 (refer to FIG. 1).

Furthermore, in the modified example shown in FIG. 23 and FIG. 24, the sensor element 100 may have the same configuration as the sensor chip 50 of the first embodiment. In this case, the terminals 61 to 64 are individually bonded to the first to fourth conductive layers 131 to 134. In one example, the terminal 61 is bonded to the first conductive layer 131. The terminal 62 is bonded to the second conductive layer 132. The terminal 63 is bonded to the third conductive layer 133. The terminal 64 is bonded to the fourth conductive layer 134.
In each embodiment, the positional relationship between the first detection element 51, the second detection element 52, and the detection pattern 43 in a plan view can be changed arbitrarily. In one example, the first detection element 51 may be disposed between a center of the detection pattern 43 in the X direction and one end edge in the X direction in the plan view. That is, the first detection element 51 does not need to be disposed to cross one end edge of the detection pattern 43 in the X direction. In one example, the second detection element 52 may be disposed between a center of the detection pattern 43 in the X direction and the other end edge in the X direction in the plan view. That is, the second detection element 52 does not need to be disposed to cross one end edge of the detection pattern 43 in the X direction.
In each embodiment, one of the first detection element 51 and the second detection element 52 may be omitted. In this case, the arrangement position of the non-omitted detection element can be changed arbitrarily within a range in which the magnetic field of the detection pattern 43 can be detected.

One or more of the various examples described in the present disclosure can be combined to the extent that no technical contradict contradiction.

The term “on” as used in the present disclosure includes the meanings of “on” and “above” unless it is clearly indicated otherwise by the context. Thus, for example, the expression “a first element is disposed on a second element” is intended to mean that in one embodiment, the first element may be directly disposed on and in contact with the second element, while in another embodiment, the first element may be disposed above the second element without contacting the second element. That is, the term “on” does not exclude the structure in which other elements are formed between the first element and the second element.

The Z direction used in the present disclosure does not need to be the vertical direction, nor does it need to completely coincide with the vertical direction. Thus, various structures according to the present disclosure are not limited to the “up” and “down” in the Z direction described in the present disclosure being vertical “up” and “down.” For example, the X direction may be the vertical direction, or the Y direction may be the vertical direction.

### <Appendix>

The technical ideas that can be understood from the present disclosure are described below. Furthermore, the components described in the appendix are referenced with reference numerals corresponding to the components in the above embodiments for the ease of understanding, but not for the purpose of limitation. The reference numerals are shown as examples for ease of understanding, and the components described in each appendix should not be limited to the components indicated by the reference numerals.

### [Appendix 1]

A semiconductor device (10), including:
a substrate (20) including a first substrate surface (20S) and a second substrate surface (20R) opposite to the first substrate surface (20S);
a wiring pattern (30) including a first wiring pattern (31) provided on the first substrate surface (20S); and
a sensor chip (50) used to detect a current flowing through the wiring pattern (30),
wherein the first wiring pattern (31) includes a detection pattern (43) having a predetermined width,
the sensor chip (50) is mounted on the first substrate surface (20S) in a state of being disposed to cross the detection pattern (43), and
the sensor chip (50) includes a detection element (51/52) that detects a magnetic field generated by a current flowing through the detection pattern (43).

### [Appendix 2]

The semiconductor device of Appendix 1, wherein the detection element (51/52) includes a first detection element (51) and a second detection element (52) which are provided on both sides of the detection pattern (43) in a width direction (X) with respect to the detection pattern (43) when viewed from a thickness direction (Z) of the substrate (20) and are disposed opposite to each other in the width direction (X) via the detection pattern (43).

### [Appendix 3]

The semiconductor device of Appendix 1 or 2, wherein a gap (GP) is provided between the sensor chip (50) and the detection pattern (43) in a thickness direction (Z) of the substrate (20).

### [Appendix 4]

The semiconductor device of Appendix 3, wherein a distance (DA) between the detection element (51/52) and the detection pattern (43) in the thickness direction (Z) of the substrate (20) is smaller than a thickness (TC) of the detection pattern (43).

### [Appendix 5]

The semiconductor device of any one of Appendices 1 to 4, wherein the first wiring pattern (31) includes:
a first pattern (41) extending in a first direction (Y);
a second pattern (42) provided at a position spaced apart from the first pattern (41) in the first direction (Y) and extending in the first direction (Y); and
the detection pattern (43) provided between the first pattern (41) and the second pattern (42) and connecting the first pattern (41) and the second pattern (42),
wherein the first pattern (41) has a first width (W1), which is a length in a second direction (X) orthogonal to the first direction (Y) when viewed from a thickness direction (Z) of the substrate (20),
the second pattern (42) has a second width (W2), which is a length in the second direction (X),
the detection pattern (43) has a connection width (WC), which is a length in the second direction (X),
the connection width (WC) is narrower than the first width (W1) and the second width (W2), and
the sensor chip (50) is mounted on the first substrate surface (20S) in a state of being disposed to cross the detection pattern (43).

### [Appendix 6]

The semiconductor device of Appendix 5, wherein a length (LC) of the detection pattern (43) in the first direction (Y) is shorter than a length (L1) of the first pattern (41) in the first direction (Y) and a length (L2) of the second pattern (42) in the first direction (Y).

### [Appendix 7]

The semiconductor device of Appendix 5 or 6, wherein the first pattern (41) includes:
a first portion (41A) having the first width (W1); and
a second portion (41B) that narrows from the first portion (41A) toward the detection pattern (43).

### [Appendix 8]

The semiconductor device of any one of Appendices 5 to 7, wherein the second pattern (42) includes:
a first portion (42A) having the second width (W2); and
a second portion (42B) that narrows from the first portion (42A) toward the detection pattern (43).

### [Appendix 9]

The semiconductor device of any one of Appendices 5 to 8, wherein the sensor chip (50) includes a plurality of terminals (61 to 64), and
the sensor chip (50) is disposed such that the plurality of terminals (61 to 64) are disposed in a space (SP) provided in the second direction (X) of the detection pattern (43).

### [Appendix 10]

The semiconductor device of Appendix 9, wherein the plurality of terminals (61 to 64) are disposed inside outer edges of the first pattern (41) and the second pattern (42) when viewed from the first direction (Y).

### [Appendix 11]

The semiconductor device of Appendix 9 or 10, further including a plurality of sensor patterns (71 to 74) provided on the first substrate surface (20S) to which the plurality of terminals (61 to 64) are individually connected,
wherein an upper surface (71S to 74S) of each of the plurality of sensor patterns (71 to 74) is positioned closer to the first substrate surface (20S) than an upper surface (43S) of the detection pattern (43).

### [Appendix 12]

The semiconductor device of any one of Appendices 5 to 11, wherein the substrate (20) is a multilayer substrate,
a heat dissipation pattern (32 to 34) insulated from the first wiring pattern (31) is provided within the substrate (20), and
the heat dissipation pattern (32 to 34) has a heat dissipation width (WP) larger than both the first width (W1) and the second width (W2).

### [Appendix 13]

The semiconductor device of Appendix 12, wherein the substrate (20) includes:
a first base material (21) including the first substrate surface (20S);
a second base material (22) including the second substrate surface (20R); and
a third base material (23) provided between the first base material (21) and the second base material (22), and
the heat dissipation pattern includes:
a first heat dissipation pattern (32) provided between the first base material (21) and the third base material (23);
a second heat dissipation pattern (33) provided between the second base material (22) and the third base material (23); and
a third heat dissipation pattern (34) provided on the second substrate surface (20R).

### [Appendix 14]

The semiconductor device of any one of Appendices 5 to 11, wherein the substrate (20) is a multilayer substrate including a laminated structure in which the first base material (21) and the second base material (22) are laminated,
the first base material (21) includes the first substrate surface (20S),
the second base material (22) includes the second substrate surface (20R),
the wiring pattern (30) is provided between the first base material (21) and the second base material (22) and includes a second wiring pattern (35) electrically connected to the first wiring pattern (31), and
each of the first wiring pattern (31) and the second wiring pattern (35) includes the first pattern (41), the second pattern (42), and the detection pattern (43).

### [Appendix 15]

The semiconductor device of Appendix 14, wherein the wiring pattern (30) includes at least one through hole (36) connecting the first wiring pattern (31) and the second wiring pattern (32) in the thickness direction (Z) of the substrate (20).

### [Appendix 16]

The semiconductor device of Appendix 15, wherein the through hole (36) is not provided in the detection pattern (43) and is provided in at least one of the first pattern (41) and the second pattern (42).

### [Appendix 17]

The semiconductor device of any one of Appendices 14 to 16, wherein the substrate (20) includes a third base material (23) provided between the first base material (21) and the second base material (22),
the second wiring pattern (35) is provided between the first base material (21) and the third base material (23),
the semiconductor device includes:
a second heat dissipation pattern (33) provided between the second base material (22) and the third base material (23); and
a third heat dissipation pattern (34) provided on the second substrate surface (20R),
wherein both the second heat dissipation pattern (33) and the third heat dissipation pattern (34) have a heat dissipation width (WP) larger than both the first width (W1) and the second width (W2).

### [Appendix 18]

The semiconductor device of Appendix 2, wherein the sensor chip (50) includes:
a third detection element (53) disposed alongside the first detection element (51) in a direction (Y) in which the detection pattern (43) extends; and
a fourth detection element (54) disposed at a same position as the third detection element (53) and alongside the second detection element (52) in the direction (Y) in which the detection pattern (43) extends.

### [Appendix 19]

The semiconductor device of any one of Appendices 1 to 18, wherein the semiconductor device (10) is used when the current flowing through the detection pattern (43) is 10 A or more.

[Appendix 20]

The semiconductor device of any one of Appendices 1 to 19, wherein the detection element (51/52) is a Hall element.

### [Appendix 21]

The semiconductor device of Appendix 11, wherein the upper surface (71S to 74S) of the plurality of sensor patterns (71 to 74) is flush with the first substrate surface (20S).

### [Appendix 22]

The semiconductor device of any one of Appendices 13 to 17, wherein the first width (W1) of the first pattern (41) is equal to the second width (W2) of the second pattern (42).

### [Appendix 23]

The semiconductor device of Appendix 17, wherein both the second heat dissipation pattern (33) and the third heat dissipation pattern (34) are electrically insulated from both the first wiring pattern (31) and the second wiring pattern (35).

### [Appendix 24]

The semiconductor device of Appendix 11, wherein a package structure of the sensor chip (50) is WLCSP.

### [Appendix 25]

The semiconductor device of Appendix 24, wherein the sensor chip (50) includes:
a semiconductor substrate (55); and
a semiconductor layer (56) provided on the semiconductor substrate (55),
wherein the detection element (51/52) is provided in the semiconductor layer (56),
the semiconductor layer (56) is disposed closer to the detection pattern (43) than the semiconductor substrate (55), and
the plurality of terminals (61 to 64) are provided on a side of the semiconductor layer (56) that is opposite to the semiconductor substrate (55).

### [Appendix 26]

The semiconductor device of Appendix 24 or 25, wherein the plurality of terminals (61 to 64) are disposed on both sides of the detection pattern (43) in the width direction (X) of the detection pattern (43).

### [Appendix 27]

The semiconductor device of Appendix 11, wherein a package structure of the sensor chip (50) is SOP.

### [Appendix 28]

The semiconductor device of Appendix 27, wherein the sensor chip (50) includes: a semiconductor substrate (55);
a semiconductor layer (56) provided on the semiconductor substrate (55); and a sealing resin (90) that seals the semiconductor substrate (55) and the semiconductor layer (56),
wherein the detection element (51/52) is provided in the semiconductor layer (56).

### [Appendix 29]

The semiconductor device of Appendix 2, wherein the sensor chip (50) includes:
a third detection element (53) disposed alongside the first detection element (51) on a side of the first detection element (51) that is opposite to the second detection element (52) in the width direction (X); and
a fourth detection element (54) disposed alongside the second detection element (52) on a side of the second detection element (52) that is opposite to the first detection element (51) in the width direction (X).

### [Appendix 30]

The semiconductor device of Appendix 29, wherein the third detection element (53) is disposed outward from the detection pattern (43) in the width direction (X), and
the fourth detection element (54) is disposed outward from the detection pattern (43) in the width direction (X).

### [Appendix 31]

The semiconductor device of Appendix 2, wherein the sensor chip (50) includes an arithmetic circuit (80) configured to output a signal corresponding to outputs from the first detection element (51) and the second detection element (52).

### [Appendix 32]

The semiconductor device of Appendix 31, wherein the arithmetic circuit (80) is configured to output a signal corresponding to a value of a current flowing through the detection pattern (43) based on a difference between an output voltage of the first detection element (51) and an output voltage of the second detection element (52).

### [Appendix 33]

The semiconductor device of Appendix 18, wherein the sensor chip (50) includes a arithmetic circuit (80) configured to output a signal corresponding to outputs from the first detection element (51), the second detection element (52), the third detection element (53), and the fourth detection element (54), and
the arithmetic circuit (80) is configured to output a signal corresponding to a value of a current flowing through the detection pattern (43) based on an average value of a difference between an output voltage of the first detection element (51) and an output voltage of the second detection element (52), and a difference between an output voltage of the third detection element (53) and an output voltage of the fourth detection element (54).

### [Appendix 34]

The semiconductor device of Appendix 31 or 32, wherein the arithmetic circuit (80) includes:
a subtractor circuit (82) calculating the difference between the output voltage of the first detection element (51) and the output voltage of the second detection element (52);
a signal processing circuit (84) converting an analog signal into a digital signal; and
an analog front-end (83) connecting the subtractor circuit (82) and the signal processing circuit (84).

### [Appendix 35]

The semiconductor devices of any one of Appendices 31 to 34, wherein the sensor chip (50) includes:
a semiconductor substrate (55); and
a semiconductor layer (56) provided on the semiconductor substrate (55),
wherein both the detection element (51/52) and the arithmetic circuit (80) are provided in the semiconductor layer (56).

### [Appendix 36]

The semiconductor devices of any one of Appendices 1 to 18, wherein the semiconductor device (10) is used when the current flowing through the detection pattern (43) is 20 A or more.

### [Appendix 37]

A sensor chip (50), used to detect a current flowing through a wiring pattern (30) provided on a first substrate surface (20S) of a substrate and mounted on the first substrate surface (20S) in a state of being disposed to cross a detection pattern (43) of the wiring pattern (30),
including a detection element (51/52) for detecting a magnetic field generated by a current flowing through the detection pattern (43).

The above description is merely exemplary. Those skilled in the art can recognize that, in addition to the components and methods (manufacturing processes) listed for the purpose of explaining the techniques of the present disclosure, many more possible combinations and substitutions are possible. The present disclosure is intended to encompass all alternatives, modifications, and changes within the scope of the present disclosure, including the claims.

1. A semiconductor device, including:
a substrate including a first substrate surface and a second substrate surface opposite to the first substrate surface;
a wiring pattern including a first wiring pattern provided on the first substrate surface; and
a sensor chip used to detect a current flowing through the wiring pattern,
wherein the first wiring pattern includes a detection pattern having a predetermined width,
the sensor chip is mounted on the first substrate surface in a state of being disposed to cross the detection pattern, and
the sensor chip includes a detection element that detects a magnetic field generated by a current flowing through the detection pattern.

2. The semiconductor device of claim 1, wherein the detection element includes a first detection element and a second detection element which are provided on both sides of the detection pattern in a width direction with respect to the detection pattern when viewed from a thickness direction of the substrate and are disposed opposite to each other in the width direction via the detection pattern.

3. The semiconductor device of claim 1, wherein a gap is provided between the sensor chip and the detection pattern in a thickness direction of the substrate.

4. The semiconductor device of claim 3, wherein a distance between the detection element and the detection pattern in the thickness direction of the substrate is smaller than a thickness of the detection pattern.

5. The semiconductor device of claim 1, wherein the first wiring pattern includes:
a first pattern extending in a first direction;
a second pattern provided at a position spaced apart from the first pattern in the first direction and extending in the first direction; and
the detection pattern provided between the first pattern and the second pattern and connecting the first pattern and the second pattern,
wherein the first pattern has a first width, which is a length in a second direction orthogonal to the first direction when viewed from a thickness direction of the substrate,
the second pattern has a second width, which is a length in the second direction,
the detection pattern has a connection width, which is a length in the second direction,
the connection width is narrower than the first width and the second width, and
the sensor chip is mounted on the first substrate surface in a state of being disposed to cross the detection pattern.

6. The semiconductor device of claim 5, wherein a length of the detection pattern in the first direction is shorter than a length of the first pattern in the first direction and a length of the second pattern in the first direction.

7. The semiconductor device of claim 5, wherein the first pattern includes:
a first portion having the first width; and
a second portion that narrows from the first portion toward the detection pattern.

8. The semiconductor device of claim 5, wherein the second pattern includes:
a first portion having the second width; and
a second portion that narrows from the first portion toward the detection pattern.

9. The semiconductor device of claim 5, wherein the sensor chip includes a plurality of terminals, and
the sensor chip is disposed such that the plurality of terminals are disposed in a space provided in the second direction of the detection pattern.

10. The semiconductor device of claim 9, wherein the plurality of terminals are disposed inside outer edges of the first pattern and the second pattern when viewed from the first direction.

11. The semiconductor device of claim 9, further including a plurality of sensor patterns provided on the first substrate surface to which the plurality of terminals are individually connected,
wherein an upper surface of each of the plurality of sensor patterns is positioned closer to the first substrate surface than an upper surface of the detection pattern.

12. The semiconductor device of claim 5, wherein the substrate is a multilayer substrate, a heat dissipation pattern insulated from the first wiring pattern is provided within the substrate, and
the heat dissipation pattern has a heat dissipation width larger than both the first width and the second width.

13. The semiconductor device of claim 12, wherein the substrate includes:
a first base material including the first substrate surface;
a second base material including the second substrate surface; and
a third base material provided between the first base material and the second base material, and
the heat dissipation pattern includes:
a first heat dissipation pattern provided between the first base material and the third base material;
a second heat dissipation pattern provided between the second base material and the third base material; and
a third heat dissipation pattern provided on the second substrate surface.

14. The semiconductor device of claim 5, wherein the substrate is a multilayer substrate including a laminated structure in which the first base material and the second base material are laminated,
the first base material includes the first substrate surface,
the second base material includes the second substrate surface,
the wiring pattern is provided between the first base material and the second base material and includes a second wiring pattern electrically connected to the first wiring pattern, and
each of the first wiring pattern and the second wiring pattern includes the first pattern, the second pattern, and the detection pattern.

15. The semiconductor device of claim 14, wherein the wiring pattern includes at least one through hole connecting the first wiring pattern and the second wiring pattern in the thickness direction of the substrate.

16. The semiconductor device of claim 15, wherein the through hole is not provided in the detection pattern and is provided in at least one of the first pattern and the second pattern.

17. The semiconductor device of claim 14, wherein the substrate includes a third base material provided between the first base material and the second base material,
the second wiring pattern is provided between the first base material and the third base material,
the semiconductor device includes:
a second heat dissipation pattern provided between the second base material and the third base material; and
a third heat dissipation pattern provided on the second substrate surface,
wherein both the second heat dissipation pattern and the third heat dissipation pattern have a heat dissipation width larger than both the first width and the second width.

18. The semiconductor device of claim 2, wherein the sensor chip includes:
a third detection element disposed alongside the first detection element in a direction in which the detection pattern extends; and
a fourth detection element disposed at a same position as the third detection element and alongside the second detection element in the direction in which the detection pattern extends.

19. The semiconductor device of claim 1, wherein the semiconductor device is used when the current flowing through the detection pattern is 10 A or more.

20. The semiconductor device of claim 1, wherein the detection element is a Hall element.
